(19) United States
(12) Patent Application Publication
(10) Pub. No.: US 2015/0303332 A1
(43) Pub. Date: Oct. 22, 2015

(54) ANODES, SOLAR CELLS AND METHODS OF MAKING SAME

(71) Applicant: NORTHWESTERN UNIVERSITY, Evanston, IL (US)

(72) Inventors: Robert P.H. Chang, Glenview, IL (US); Byunghong Lee, Evanston, IL (US); Shiqiang Li, Evanston, IL (US); Peijun Guo, Evanston, IL (US)

(21) Appl. No.: 14/629,039

(22) PCT Filed: Aug. 22, 2013
(86) PCT No.: PCT/US13/56291

§ 371 Date: Feb. 23, 2015

Related U.S. Application Data
(60) Provisional application No. 61/691,877, filed on Aug. 22, 2012.

(51) Int. Cl. H01L 31/0352; H01G 9/20; H01L 31/18

(52) U.S. Cl. CPC H01L 31/035227; H01L 31/1884; H01G 9/2031; H01L 31/035218

(57) ABSTRACT

Anodes, solar cells utilizing said anodes, and methods of manufacturing the same are disclosed. More specifically, the anodes disclosed herein may comprise a substrate made from a conducting material, and further comprise an array of nanowires projecting from the substrate. Solar cells that utilize an anode disclosed herein include nanoparticle-based cells and organic photovoltaic cells. The nanoparticle-based cells include dye sensitized solar cells and quantum dot/rod sensitized solar cells. The organic photovoltaic cells can include polymer solar cells, and hybrid organic/inorganic cells utilizing a combination of nanoparticle based and polymer solar cells.

### CROSS-REFERENCE TO RELATED APPLICATIONS

This application claims benefit of priority under 35 U.S.C. 119 to U.S. provisional patent application Ser. No. 61/691,877 filed Aug. 22, 2012, and entitled ANODES, SOLAR CELLS AND METHODS OF MAKING SAME, the contents of which are herein incorporated by reference in its entirety.

### TECHNICAL FIELD

The present disclosure relates to anodes, solar cells utilizing said anodes, and methods of manufacturing the same.

### BACKGROUND

Most third generation solar cells devices utilize a design in which a particulate semiconducting active layer is sandwiched between an anode and a cathode (FIG. 1). While this planar geometry is easy to manufacture, it suffers from the shortcoming that as the active layer thickness is increased to improve photon collection, cell efficiency also begins to suffer as resistive losses due to charge recombination, traps, and loss of excitons increases (FIG. 2). At certain thicknesses specific to each cell design, the restive losses due to increasing active layer thickness outweigh the conversion of captured photons into usable energy and the cell efficiency may decrease (FIG. 2). Moreover, as nanoparticle film thickness is increased, the conversion efficiency of each nanoparticle decreases (FIG. 3).

Alternative devices have been explored to mitigate these inherent resistive losses. For example, Kang et al., Dye-Sensitized Solar Cell and Method of Manufacturing the Same, EP2073226A2, 2009, teaches a solar cell wherein the anode is comprised of a conductive substrate having semiconducting nanorods grown from the substrate. Lee et al., Solid-State Dye Sensitized Solar Cells Based on ZnO Nanoparticle and Nanorod Array Hybrid Photoanodes, Nanoscale Research Letters, 2011, teaches an anode wherein the substrate is comprised of a semiconducting material having semiconducting nanorods grown from the substrate. Lastly, Faglia et al., Nanostructured Materials Improve Efficiency in Excitonic Solar Cells, SPIE, 2009, teaches an anode having single-crystalline semiconducting zinc oxide nanowires grown from the substrate.

Each of these devices has its disadvantages. First, each of these devices utilizes a nanowire/nanorod comprised of a semiconducting material. Additionally, the nanowires/nanorods in each of these devices are poorly oriented with respect to their substrate.

### SUMMARY

In a first embodiment, an anode for use in a solar cell utilizing a nanoparticle based active layer is disclosed. The anode includes a substrate and two or more nanowires. The substrate is comprised of a conductive material. The conductive materials within the scope of this disclosure include metals and transparent conducting oxides. The transparent conducting oxides from which the substrate is made include indium tin oxide, fluorine tin oxide, and doped zinc oxide.

The two or more nanowires include a conducting material. The conducting materials within the scope of this disclosure include metals and transparent conducting oxides. The metals can include gold, silver and copper, while the transparent conducting oxides can include indium tin oxide, fluorine tin oxide and doped zinc oxide.

The two or more nanowires have a first end, a second end and a longitudinal axis therebetween. The first end is attached to the substrate. The angle between the longitudinal axis and the substrate is at least 70 degrees and is less than or equal to 90 degrees. Additionally, the distance between the first end and the second end of each nanowire is at least 5 nanometers, but is less than or equal to 50 microns. The distance between the first ends of two nanowires is at least 50 nanometers but is less than or equal to 5 microns. The two or more nanowires have a diameter of at least 5 nanometers, but less than or equal to 1 micrometer. Moreover, the two or more nanowires possess geometry with respect to each other. The geometry may be chosen from the group comprising triangular, square, pentagonal, hexagonal, heptagonal and octagonal.

Lastly, the nanowires are coated with a non-conducting material. The non-conducting material may be a semiconducting material, but can also be chosen from the group comprising titanium dioxide, zinc oxide and gallium nitride. The thickness of the non-conducting material is at least 0.05 nanometers, but is less than or equal to 500 nanometers.

In a second embodiment, a solar cell utilizing a nanoparticle based active layer is disclosed. This solar cell includes an anode having a substrate with two or more nanowires and a cathode in electrical communication with said anode. The substrate includes a conductive material. The conductive materials within the scope of this disclosure include metals and transparent conducting oxides. The transparent conducting oxides from which the substrate is made include indium tin oxide, fluorine tin oxide and doped zinc oxide.

The two or more nanowires include a conducting material. The conducting materials within the scope of this disclosure include metals and transparent conducting oxides. The metals can include gold, silver and copper, while the transparent conducting oxides can include indium tin oxide, fluorine tin oxide and doped zinc oxide.

The two or more nanowires in this embodiment have a first end, a second end and a longitudinal axis therebetween. The first end is attached to the substrate. The angle between the longitudinal axis and the substrate is at least 70 degrees and is less than or equal to 90 degrees. Additionally, the distance between the first end and the second end of each nanowire is at least 5 nanometers, but is less than or equal to 50 microns. The distance between the first ends of two nanowires is at least 50 nanometers but is less than or equal to 5 microns. The two or more nanowires have a diameter of at least 5 nanometers, but less than or equal to 1 micrometer. Moreover, the two or more nanowires possess geometry with respect to each other. The geometry may be chosen from the group comprising triangular, square, pentagonal, hexagonal, heptagonal and octagonal.

The nanowires are coated with a non-conducting material. The non-conducting material may be a semiconducting material, but can also be chosen from the group comprising titanium dioxide, zinc oxide and gallium nitride. The thickness of the non-conducting material is at least 0.05 nanometers, but is less than or equal to 500 nanometers.

The solar cell also includes two or more nanoparticles disposed between the nanowires, and the nanoparticles may be comprised of a non-conductive material. The non-conductive materials within the scope of this disclosure can include titanium dioxide, zinc oxide and gallium nitride.

The nanoparticles have a particle size greater than or equal to 2 nanometers and less than or equal to 500 nanometers. Moreover, the nanoparticles are sensitized with a dye or a quantum dot/rod.

In a third embodiment, an anode for use in an organic photovoltaic solar cell is disclosed herein. The anode includes a substrate and two or more nanowires. The substrate includes a conductive material. The conductive materials within the scope of this disclosure include metals and transparent conducting oxides. The transparent conducting oxides from which the substrate may be made can include indium tin oxide, fluorine tin oxide, and doped zinc oxide.

The two or more nanowires in this embodiment include a conducting material. The conducting materials within the scope of this disclosure include metals and transparent conducting oxides. The metals can include gold, silver and copper, while the transparent conducting oxides can include indium tin oxide, fluorine tin oxide and doped zinc oxide.

The two or more nanowires in this embodiment have a first end, a second end and a longitudinal axis therebetween. The first end is attached to the substrate. The angle between the longitudinal axis and the substrate is at least 70 degrees and is less than or equal to 90 degrees. Additionally, the distance between the first end and the second end of each nanowire is at least 5 nanometers, but is less than or equal to 50 microns. The distance between the first ends of two nanowires is at least 50 nanometers but is less than or equal to 5 microns. The two or more nanowires have a diameter of at least 5 nanometers, but less than or equal to 1 micrometer. Moreover, the two or more nanowires possess geometry with respect to each other. The geometry may be chosen from the group comprising triangular, square, pentagonal, hexagonal, heptagonal and octagonal.

In a fourth embodiment, an organic photovoltaic solar cell is disclosed. This solar cell includes an anode having a substrate with two or more nanowires and a cathode in electrical communication with the anode. The substrate of the anode includes a conductive material. The conductive materials within the scope of this disclosure include metals and transparent conducting oxides. The transparent conducting oxides from which the substrate may be made can include indium tin oxide, fluorine tin oxide, and doped zinc oxide.

The two or more nanowires in this embodiment include a conducting material. The conducting materials within the scope of this disclosure include metals and transparent conducting oxides. The metals can include gold, silver and copper, while the transparent conducting oxides can include indium tin oxide, fluorine tin oxide and doped zinc oxide.

The two or more nanowires in this embodiment have a first end, a second end and a longitudinal axis therebetween. The first end is attached to the substrate. The angle between the longitudinal axis and the substrate is at least 70 degrees and is less than or equal to 90 degrees. Additionally, the distance between the first end and the second end of each nanowire is at least 5 nanometers, but is less than or equal to 50 microns. The distance between the first ends of two nanowires is at least 50 nanometers but is less than or equal to 5 microns. The two or more nanowires have a diameter of at least 5 nanometers, but less than or equal to 1 micrometer. Moreover, the two or more nanowires possess geometry with respect to each other. The geometry may be chosen from the group comprising triangular, square, pentagonal, hexagonal, heptagonal and octagonal.

Additionally, the nanowires of this embodiment are coated with a first layer. Preferably, the first layer is zinc oxide. Additionally, the nanowires in this embodiment may be coated with a second layer. The second layer may include PEDOT:PSS or P3HT/PCBM.

Lastly, in a fifth embodiment, a method of manufacturing an anode for use in a solar cell utilizing a nanoparticle based active layer is disclosed herein. The method includes the steps of providing a patterned array substrate that includes an array of metal dots, a dopant material and a metal oxide powder; heating the patterned any substrate under conditions to grow nanowires from the patterned array to create an anode with a nanowire array; providing a precursor and water; and exposing the anode with a nanowire any to the precursor and water under conditions to coat the nanowires.

In this embodiment, the metal dots may include gold. The dopant material may be chosen from the group comprising indium and fluorine. The metal oxide may be chosen from the group tin oxide and zinc oxide. Lastly, in this embodiment, the precursor may be titanium tetrachloride.

### BRIEF DESCRIPTION OF THE DRAWINGS

FIG. 1 depicts a schematic of a prior art embodiment of the design and operation of a traditional dye sensitized solar cell (DSSC) comprising a transparent conducting anode, a cathode, a sensitized layer of nanoparticles sandwiched between the cathode and anode, and wherein the nanoparticle layer is soaked with a liquid electrolyte. Light enters the solar cell through the anode and passes to the nanoparticle layer. The liquid electrolyte is in contact with the cathode. Photoconverted electrons leave the cell from the anode and the hole from the cathode.

FIG. 2 illustrates a prior art embodiment of the efficiency of a traditional DSSC as a function of nanoparticle film thickness. The internal resistance to charge flow in a traditional DSSC increases as the active layer thickness increases. Moreover, the highest open circuit voltage and fill factor are at the thinnest nanoparticle film thickness.

FIG. 3 illustrates a prior art embodiment of the efficiency per nanoparticle in the active layer of a traditional solar cell as a function of active layer thickness. As the thickness of nanoparticle active layer in a traditional solar cell is increased, the efficiency of the nanoparticles decreases.

FIG. 4A depicts the design of one embodiment of an anode disclosed herein having a substrate comprised of a conductive material and nanowires attached to the substrate made from a conducting material.

FIG. 4B depicts additional details of one embodiment of the relationship of nanowires to the substrate and illustrates that the nanowires may be optionally further coated with a non-conducting material.

FIG. 4C depicts details of one embodiment of an anode that may further incorporate p-type or n-type materials to create a solar cell.

FIG. 5 depicts the utilization of an anode disclosed herein in a solar cell employing a nanoparticle based active layer.

FIG. 5A depicts the design of one embodiment of an anode for a solar cell, wherein the anode includes a substrate comprised of a conductive material and nanowires attached to the substrate made from a conducting material.

FIG. 5B depicts additional details of one embodiment of the solar cell, wherein the relationship of nanowires to the substrate in the anode half cell is shown and illustrates that the nanowires may be optionally further coated with a non-conducting material.

FIG. 5C depicts details of one embodiment of the solar cell, wherein the anode half cell may further incorporate p-type or n-type materials.

FIG. 5D depicts two types of solar cells (top and bottom), wherein the top image depicts a dye-sensitized solar cell that contains an anode half cell with a TiO₂ nanoparticle layer sensitized with dye complexes, such as a Ru-based complex dye and wherein the bottom image depicts a quantum dot/rod-sensitized solar cell that contains an anode half cell with a TiO₂ nanoparticle layer sensitized with quantum dots/rods.

FIG. 6A depicts the utilization of an embodiment of an anode structure disclosed herein for use in an anode half cell of an organic photovoltaic cell.

FIG. 6B illustrates inclusion of the embodiment of the anode structure of Fig. A in a completed solar cell.

FIG. 6C illustrates an embodiment of a configuration of nanowire layers and coatings as disclosed herein.

FIG. 7 depicts the fabrication of a dye-sensitized solar cell utilizing an anode as disclosed herein, wherein structure A depicts the creation of a substrate comprised of a conductive material; structure B depicts the patterning of the substrate for the subsequent growth of nanowires on the substrate; structure C represents the growth of nanowires on the patterned substrate to create a nanowire any wherein the nanowires are comprised of a conducting material; structure D depicts the substrate having a nanowire any with its protective gold coating removed; structure E represents the nanowires having been coated with non-conducting material via atomic layer deposition; structure F depicts the infiltration of nanoparticles comprised of a non-conductive material into the space between nanowires; structure G depicts a post-treatment along with sintering of the nanoparticles; structure H depicts the photosensitization of the device by exposure to a photosensitive dye; and structure I depicts the creation of a completed solar cell utilizing an anode disclosed herein.

FIG. 8A is a representative SEM image of anodes disclosed herein illustrating that the nanowires may have different lengths.

FIG. 8B is a representative SEM image of anodes disclosed herein illustrating that the nanowires may have different lengths.

FIG. 8C demonstrates the infiltration of nanoparticles in between nanowires of an anode disclosed herein and further illustrate the non-conducting material coating on a nanowire of an anode disclosed herein.

FIG. 8D demonstrates the infiltration of nanoparticles in between nanowires of an anode disclosed herein and further illustrate the non-conducting material coating on a nanowire of an anode disclosed herein.

FIG. 9A illustrates the cracking present in a titanium dioxide nanoparticle film when a post-treatment process disclosed herein is not utilized.

FIG. 9B illustrates a titanium dioxide nanoparticle film after treatment with a titanium sol.

FIG. 9C illustrates the continuity of the titanium dioxide nanoparticle film after treatment with both a titanium sol and titanium tetrachloride.

FIG. 10 illustrates the improved performance of a titanium dioxide nanoparticle film after treatment with just a titanium sol, and then subsequently with titanium tetrachloride. As illustrated, a significant (for example, greater than 20% gain in efficiency) is seen with the use of the titanium sol and titanium tetrachloride treatments.

FIG. 11A illustrates the J-V curves of DSSC devices and those that utilize an anode disclosed herein for different TiO₂ nanoparticle thicknesses.

FIG. 11B illustrates the configuration of a solar cell utilizing an anode disclosed herein further comprising the use of a 3-D photonic crystal (PC).

FIG. 11C demonstrates the detailed internal series resistance (R_{IR}).

FIG. 11D represents an equivalent circuit of solar cells that utilize an anode disclosed herein.

FIG. 12 depicts one embodiment of an SEM image of the results of growth of non patterned (i.e., random)) ITO nano-rods.

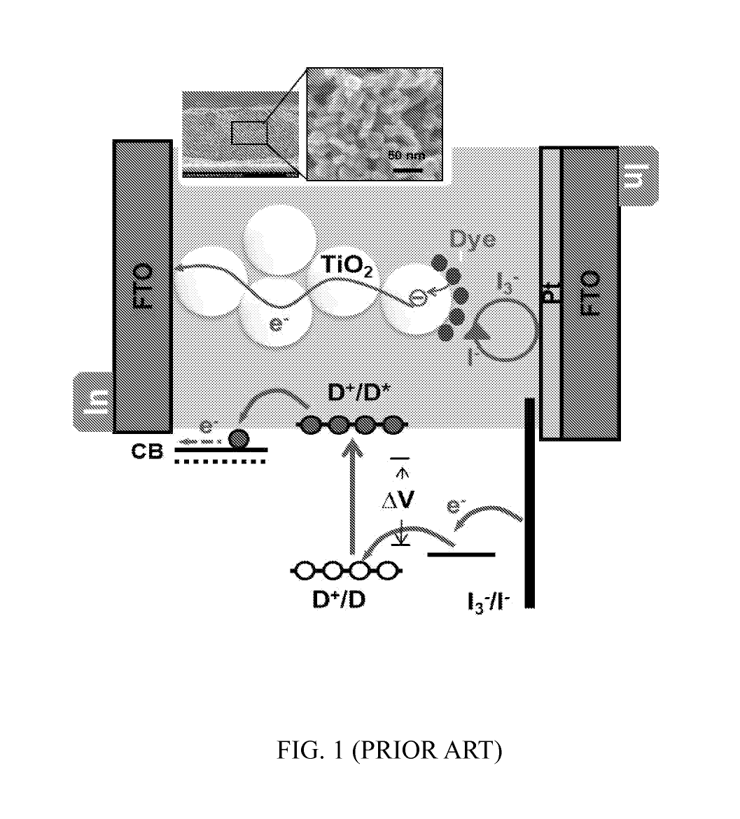

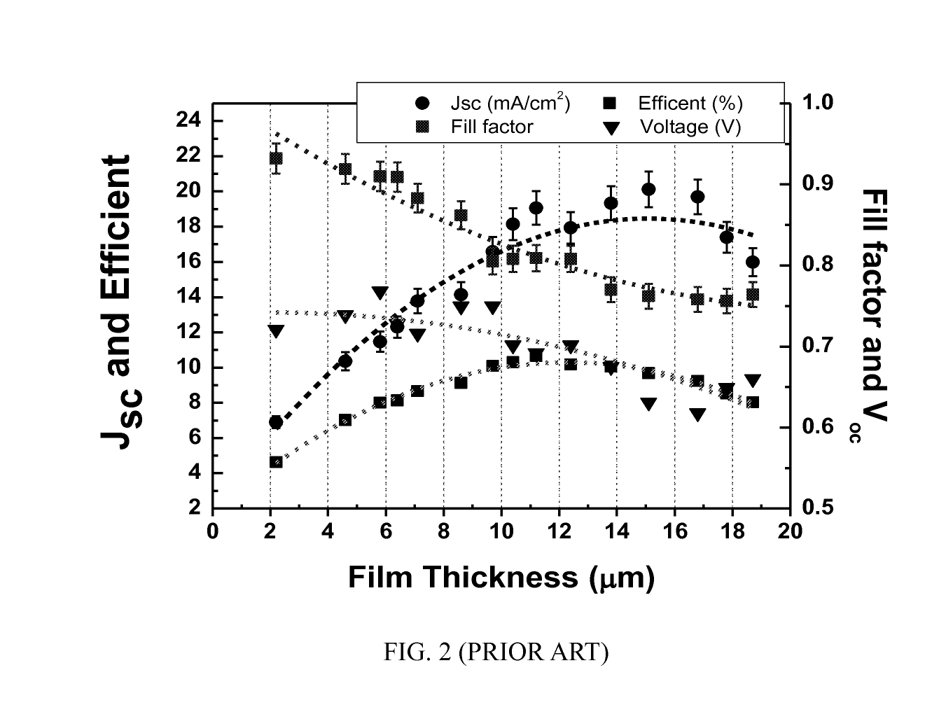

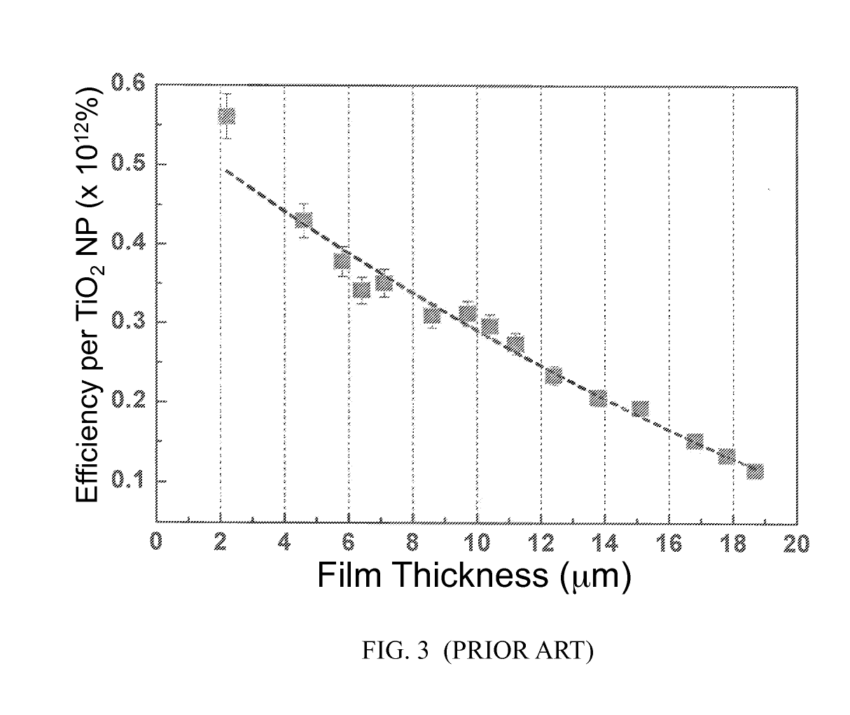

### DETAILED DESCRIPTION

The anode disclosed herein is a novel apparatus to decrease resistive losses due to charge recombination, traps, and loss of excitons in solar cells utilizing an active layer comprised of nanoparticles. First, an anode disclosed herein may utilize a substrate comprised of a conductive material. Moreover, an array of nanowires made from a conducting material may be attached to the substrate so that charge transfer through the nanowires is enhanced, and the nanowires may be substantially, if not completely, normal to the substrate so that subsequent filling with nanoparticles is improved. Lastly, the nanowires disclosed herein may be coated with a non-conducting material before nanoparticle infiltration so that subsequent filling with an electrolyte does not cause a short circuit between the anode and cathode of a completed solar cell.

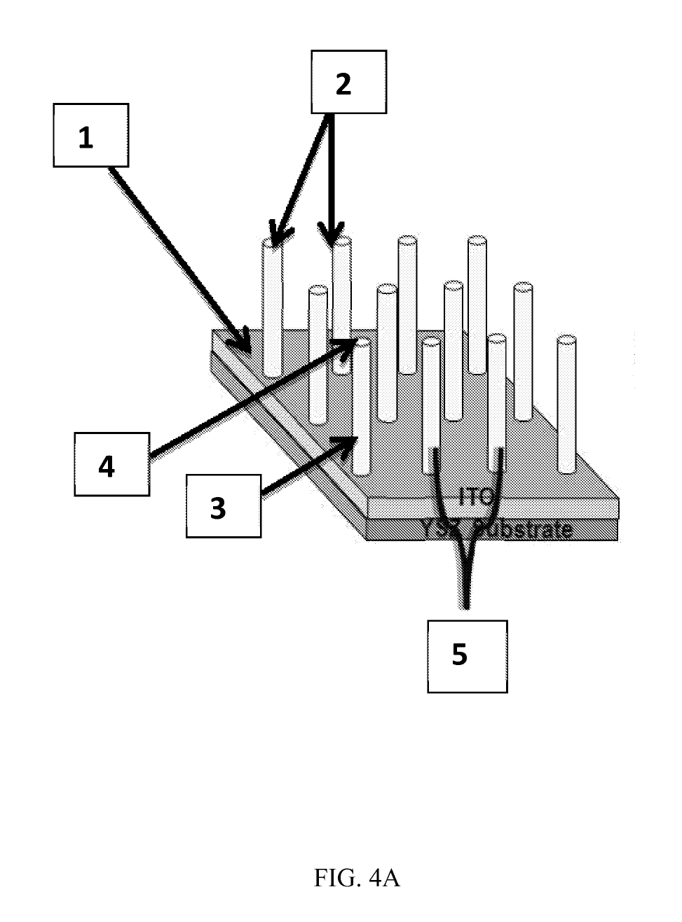

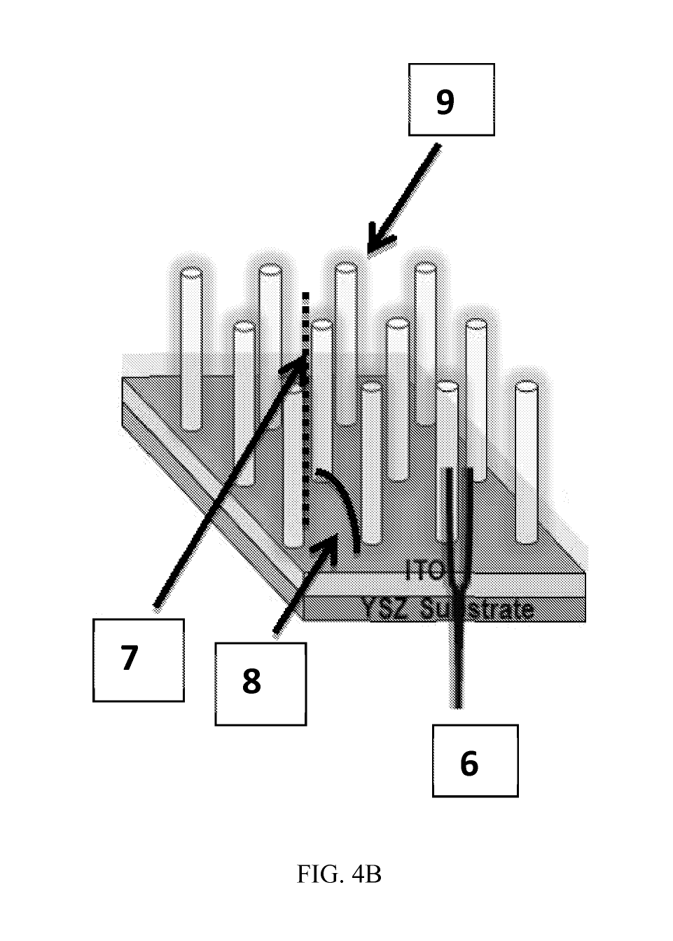

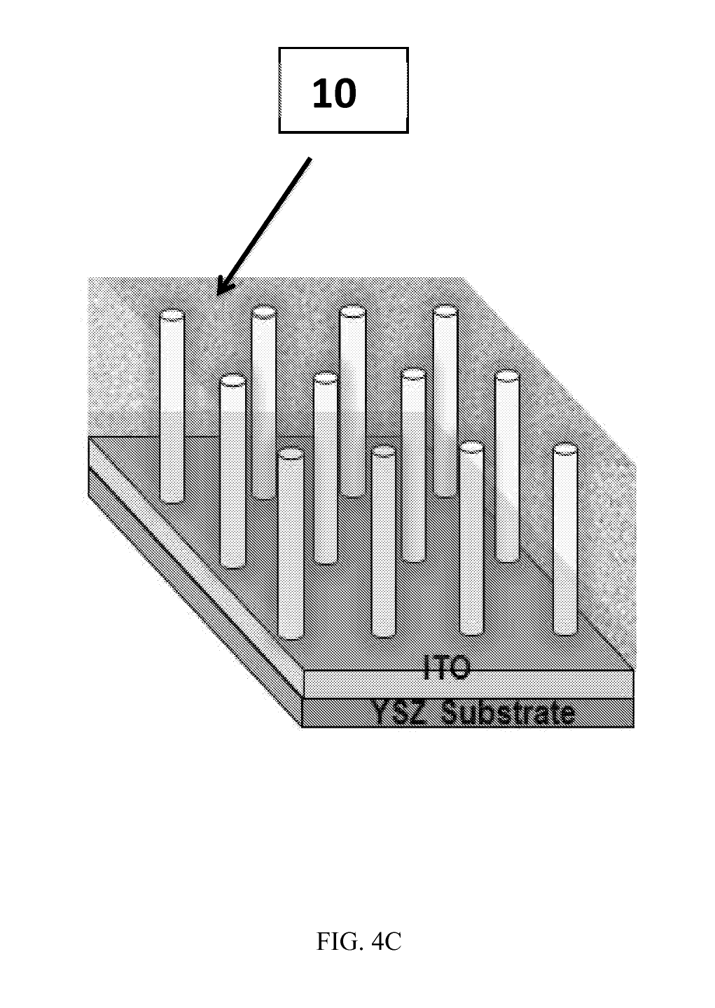

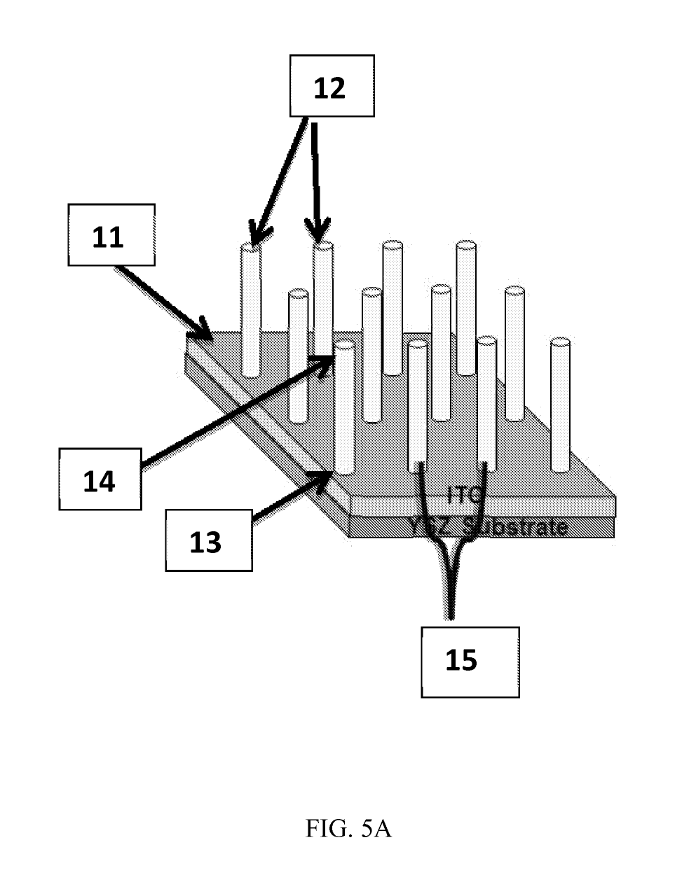

Referring to FIG. 4A, in a first embodiment, an anode for use in a solar cell utilizing a nanoparticle based active layer is disclosed. The anode includes a substrate 1 and two or more nanowires 2. The substrate includes a conductive material, and in an exemplary embodiment, the conductive material may be a transparent conducting oxide. While not meant to be limiting, and only representative, the transparent conducting oxides from which the substrate 1 may be comprised include indium tin oxide, fluorine tin oxide, and doped zinc oxide. In an alternative embodiment, the conductive material may be metal.

In this embodiment the two or more nanowires 2 include a conducting material, and in a preferred embodiment, the conducting material is a transparent conducting oxide. While not all inclusive of the transparent conducting oxides that may be utilized for the two or more nanowires 2 disclosed herein, in one embodiment the transparent conducting oxides are chosen from the group comprising indium tin oxide, fluorine tin oxide, and doped zinc oxide. In an alternative embodiment the conducting material may be metal. In this alternative embodiment, the metal may be chosen from the group comprising gold, silver, and copper.

The two or more nanowires 2 have first end 3 and a second end 4. The first end 3 of each of the two or more nanowires 2 is attached to the substrate 1. The distance between the first end and second end of each of the two or more nanowires is at least 5 nanometers, but is less than or equal to 50 microns. Moreover, the distance 5 (that is, the “pitch”) between the first end of a first nanowire and the first end of a second nanowire is at least 50 nanometers, yet is less than or equal to 5 microns. Lastly, the diameter 6 of each of the nanowires disclosed herein is at least 5 nanometer and less than or equal to 1 micrometer. Still referring to FIG. 4A, each nanowire 2 has a longitudinal axis 7 between the first end 3 and the second end 4, and includes an angle 8 between the longitudinal axis 7 and the substrate 1. In a preferred embodiment angle 8 is greater than or equal to 70 degrees and less than or equal to 90 degrees. In a more preferred embodiment angle 8 is greater than or equal to 80 degrees and less than or equal to 90 degrees.

Referring to FIG. 4B, in an exemplary embodiment of a anode that can be used for solar cell the utilizes a nanoparticle based active layer, two or more nanowires 2 are coated with a non-conducting material 9 so that subsequent filling with an electrolyte is less likely to create a short circuit between the anode and cathode of a completed solar cell. Moreover, the non-conducting material may be a semiconducting material. The non-conducting material has appropriate electrical and optical properties, to provide electrical isolation between the nanowires 2 as well as optical transparency for anode performance in a solar cell context. In an even more preferred embodiment, the non-conducting material is chosen from the group comprising oxides and nitrides having appropriate electrical and optical properties, such as titanium dioxide, zinc oxide, and gallium nitride. Lastly, the thickness of a non-conducting material disclosed herein is at least 0.05 nanometers, but is optimally less than or equal to 500 nanometers.

Subsequent to applying a non-conducting material, p-type-and-n-type-materials 10 may be infiltrated between the two or more nanowires to create a half of a solar cell (FIG. 4C). Exemplary p-type nanomaterials 10 include the class of wide band-gap semiconductors such as doped oxides (for example, TiO₂, SnO), doped nitrides, among others. Exemplary p-type nanomaterials 10 can also include the class of organic materials such as PEDOT:PSS32. Exemplary n-type nanomaterials 10 include the class of wide band-gap semiconductors such as oxides (for example, TiO₂, SnO), nitrides (for example, GaN), carbides (for example, SiC), phosphides (for example, AlGaP), among others. In a preferred embodiment, the p-type-and-n-type-materials 10 are nanoparticles.

To increase the subsequent infiltration of p-type-and-n-type-materials 10 or enhance cell efficiency, the two or more nanowires 2 disclosed herein possess geometry. This geometry can be created by varying the placement of an electron beam during an electron beam writing step used to manufacture an anode disclosed herein, although other methods to manufacture such anodes may be utilized. While the following list is not meant to be all-inclusive, and only representative of embodiments that may be utilized, the geometry between nanowires 2 may be triangular, square, pentagonal, hexagonal, heptagonal and octagonal.

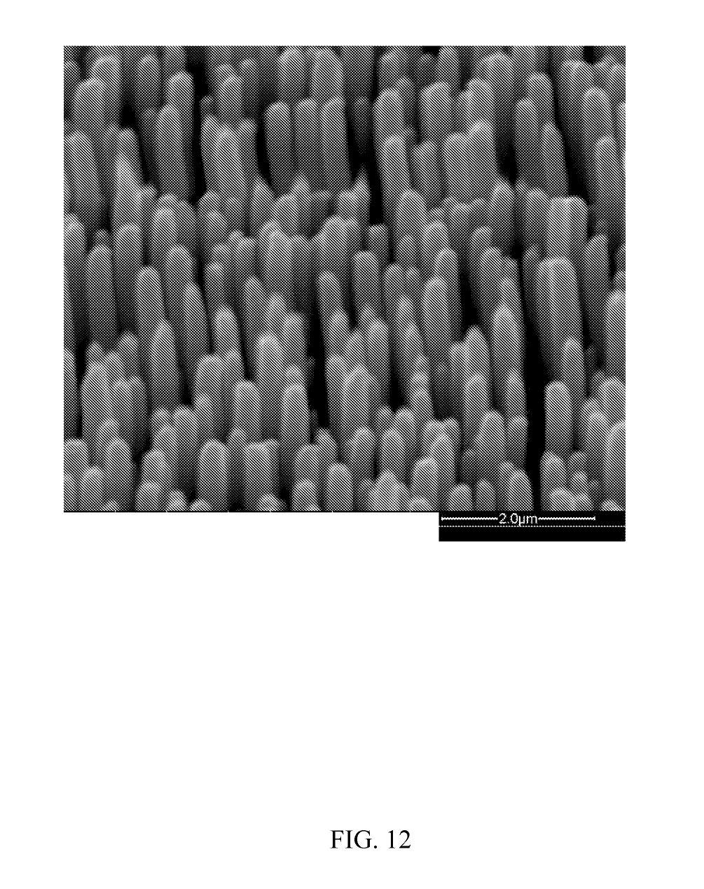

In some embodiments, the two or more nanowires 2 possess geometry having a non-patterned, random configuration (see, for example, Example 9 and FIG. 12). The advantage to a nanowire 2 geometry having a non-patterned, random configuration is that such geometries avoid the costs associated with fabricating patterned substrates for nanowire outgrowth.

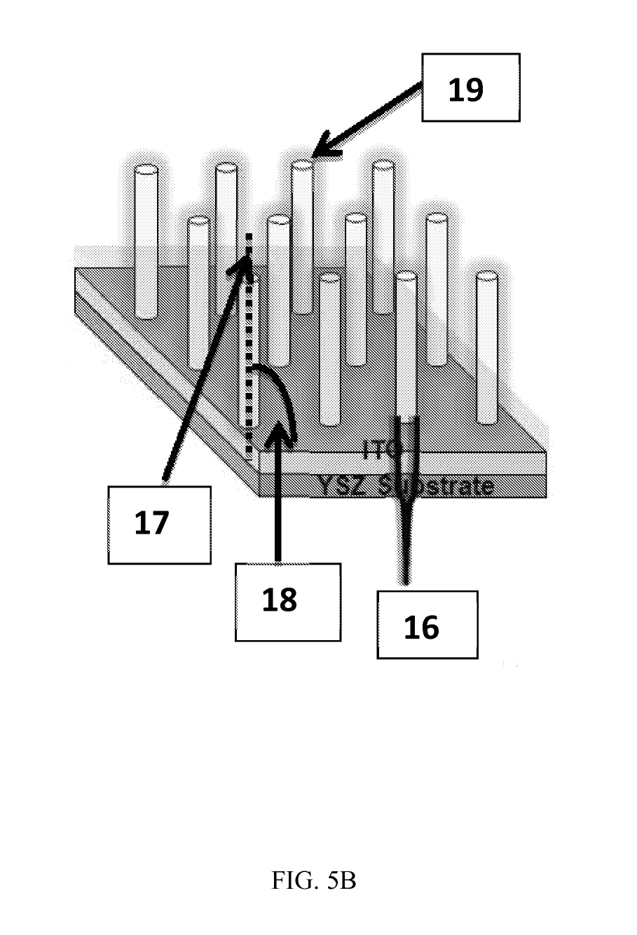

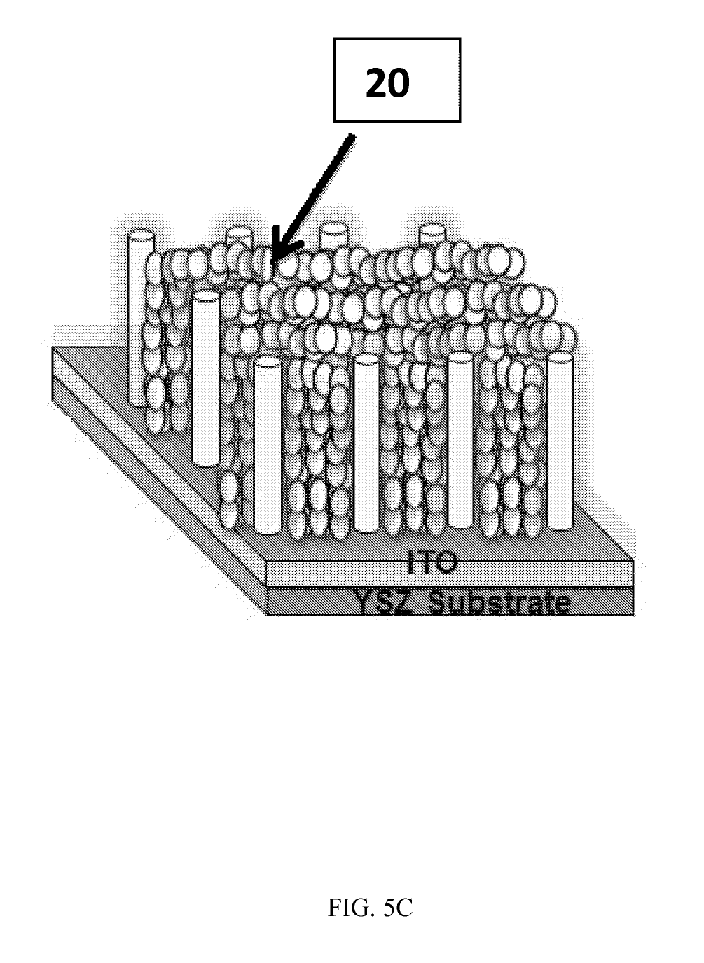

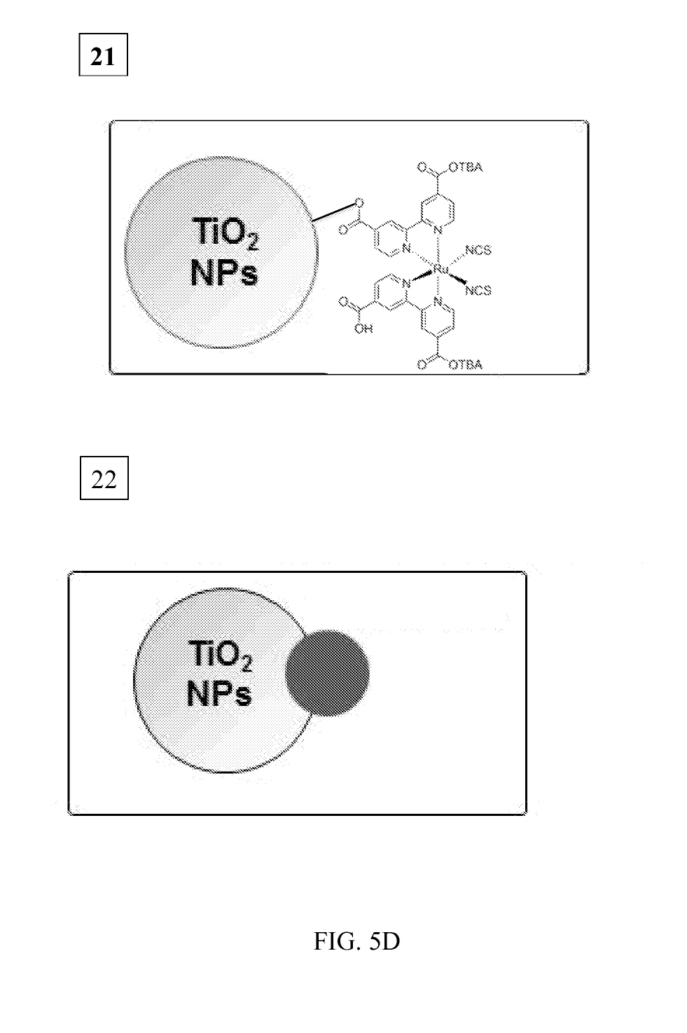

Referring to FIG. 5A, in a second embodiment, a solar cell utilizing a nanoparticle based active layer is disclosed. The solar cell has an anode half that includes a substrate 11 and two or more nanowires 12. The substrate includes a conductive material, and in an exemplary embodiment, the conductive material is a transparent conducting oxide. While not meant to be limiting, the transparent conducting oxides from which the substrate 11 may be comprised include indium tin oxide, fluorine tin oxide, and doped zinc oxide. In an alternative embodiment, the conductive material may be metal.

In this embodiment, the two or more nanowires 12 of the anode half include a conducting material, while in a preferred embodiment, the conducting material is a transparent conducting oxide. While not all inclusive of the transparent conducting oxides that may be utilized for the two or more nanowires 2 in this anode half, in one embodiment, the transparent conducting oxides are chosen from the group comprising indium tin oxide, fluorine tin oxide, and doped zinc oxide. In an alternative embodiment, the conducting material may be metal. In this alternative embodiment the metal may be chosen from the group comprising gold, silver, and copper.

The two or more nanowires 12 of this anode half have first end 13 and a second end 14. The first end 13 of each of the two or more nanowires 12 is attached to the substrate 11. The distance between the first end and second end of each of the two or more nanowires is at least 5 nanometers, but is preferably less than or equal to 50 microns. Moreover, the distance 15 (that is, the “pitch”) between the first end of a first nanowire and the first end of a second nanowire is greater than or equal to 50 nanometers, but is less than or equal to 5 microns. Lastly, the diameter 16 of each of the nanowires is at least 5 nanometers, yet is less than or equal to 1 micrometer.

Referring to FIG. 5B, each nanowire 12 has a longitudinal axis 17 between the first end 13 and the second end 14, and includes an angle 18 between the longitudinal axis 17 and the substrate 11. In a preferred embodiment angle 18 is greater than or equal to 70 degrees and less than or equal to 90 degrees. In a more preferred embodiment, angle 18 is greater than or equal to 80 degrees and less than or equal to 90 degrees.

Still referring to FIG. 5B, the two or more nanowires 12 are coated with a non-conducting material 19 so that subsequent filling with an electrolyte is less likely to create a short circuit between the anode and cathode of a completed solar cell. Moreover, the non-conducting material may be a semiconducting material. The non-conducting material have appropriate electrical and optical properties, to provide electrical isolation between the nanowires 2 as well as optical transparency for anode performance in a solar cell context. In an even more preferred embodiment, the non-conducting material is chosen from the group comprising oxides and nitrides having appropriate electrical and optical properties, such as titanium dioxide, zinc oxide, and gallium nitride. Lastly, the thickness of a non-conducting material disclosed herein is greater than or equal to 0.05 nanometers and less than or equal to 500 nanometers.

Referring to FIG. 5C, after applying the non-conducting material to the two or more nanowires, two or more nanoparticles 20 are disposed between the two or more nanowires 12. In a preferred embodiment, the nanoparticles are made from a non-conductive material. In an exemplary embodiment, the non-conductive material is chosen from the group of titanium dioxide, zinc oxide, and gallium nitride, yet this list is only meant to be representative and not all inclusive. Additionally, the nanoparticles may have a particle size that is greater than or equal to 2 nanometers and less than or equal to 500 nanometers.

To increase the subsequent infiltration of nanoparticles 20 or enhance cell efficiency, the two or more nanowires 12 disclosed herein possess geometry. This geometry can be created by varying the placement of an electron beam during an electron beam writing step used to manufacture an anode disclosed herein, although other methods to manufacture such anodes may be utilized. While the following list is not meant to be all-inclusive, and only representative of embodiments that may be utilized, the geometry between nanowires 12 may be triangular, square, pentagonal, hexagonal, heptagonal and octagonal.

Still referring to FIG. 5D, the nanoparticles 20 are treated with a sensitizing material. The sensitizing material may be a dye 21 so that a dye-sensitized solar cell is created with the anode half (FIG. 5D, Top). The dyes that may be utilized in this embodiment include ruthenium based dyes. Alternatively, the sensitizing material may be a quantum dot/rod 22 so that a quantum dot/rod sensitized solar cell is created with the anode half (FIG. 5D, Bottom). While not meant to be all encompassing of the different materials that can be utilized to make a quantum dot/rod to sensitize the anode half, the materials within the scope of this disclosure include cadmium sulfide, cadmium selenide, indium phosphide, indium arsenide and lead sulfide. Lastly, the solar cell utilizing a nanoparticle based active layer disclosed herein includes a cathode that is in electrical communication with the cathode.

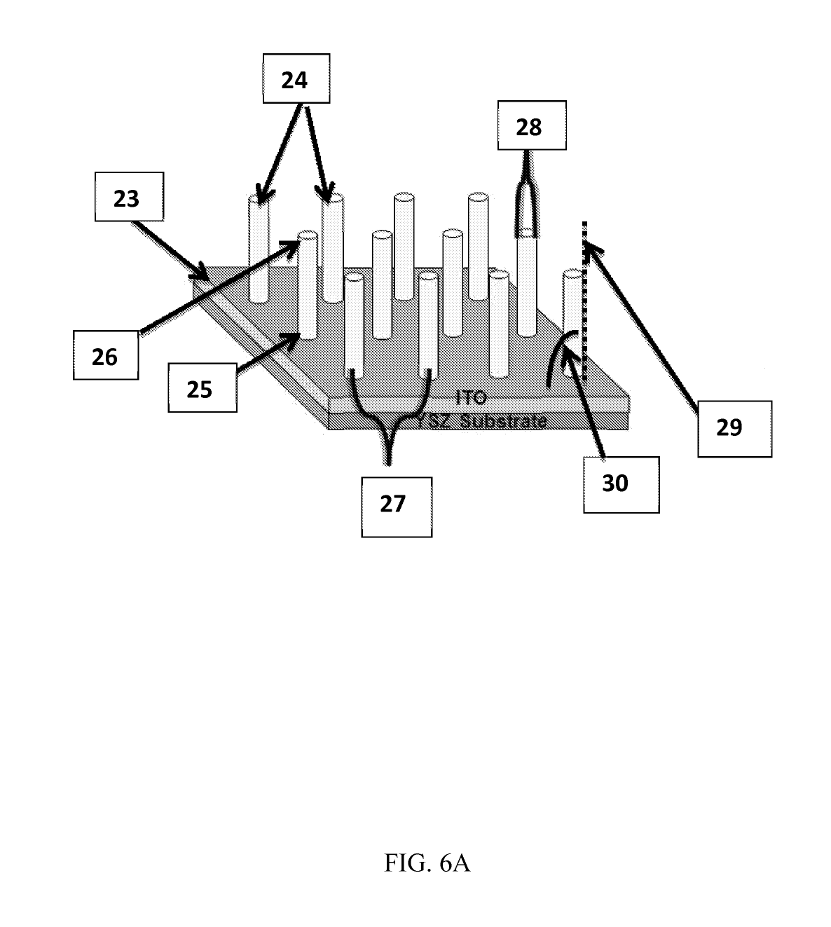

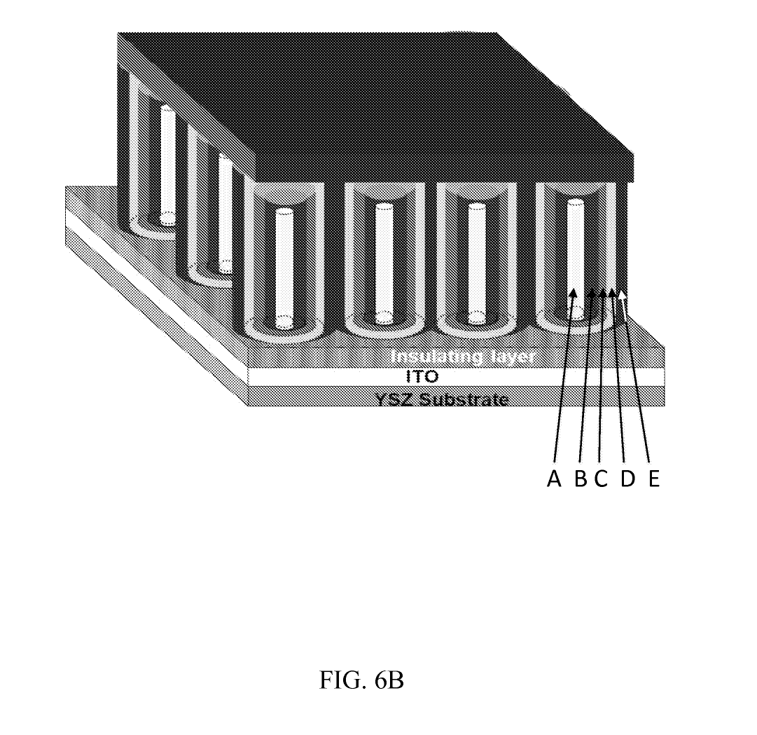

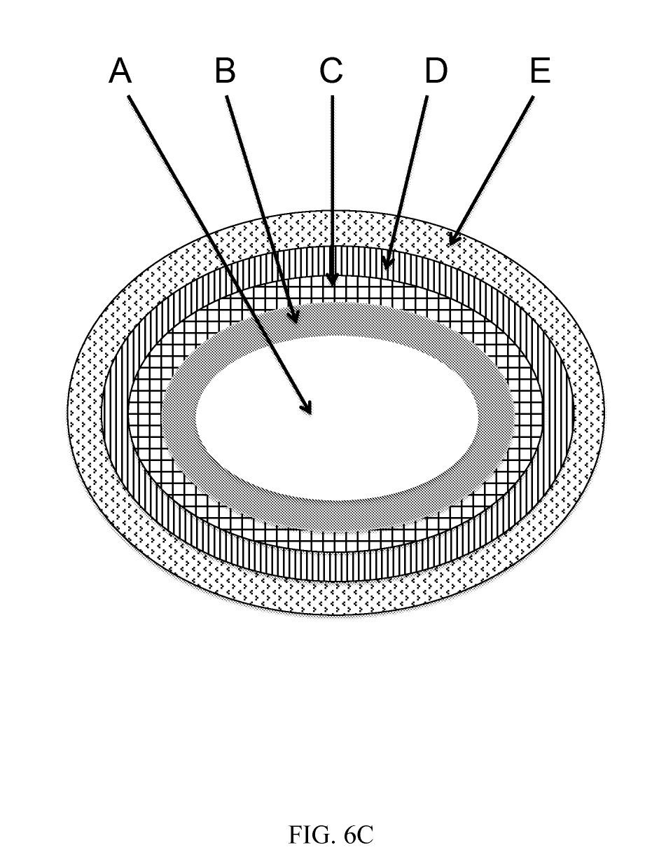

Referring to FIG. 6, in a third embodiment, an anode for use in an organic photovoltaic solar cell is disclosed. Referring to FIG. 6A, the anode includes a substrate 23 and two or more nanowires 24. The substrate includes a conductive material, and in an exemplary embodiment, the conductive material is a transparent conducting oxide. While not meant to be limiting, the transparent conducting oxides from which the substrate 23 may be comprised include indium tin oxide, fluorine tin oxide, and doped zinc oxide. In an alternative embodiment, the conductive material may be metal.

In this embodiment, the two or more nanowires 24 include a conducting material, and in a preferred embodiment, the conducting material is a transparent conducting oxide. While not all inclusive of the transparent conducting oxides that may be utilized for the two or more nanowires 24 disclosed herein, in one embodiment the transparent conducting oxides are chosen from the group comprising indium tin oxide, fluorine tin oxide, and doped zinc oxide. In an alternative embodiment the conducting material may be metal. In this alternative embodiment the metal may be chosen from the group comprising gold, silver, and copper.

In some embodiments, substrate 23 and nanowires 24 are composed of the same compositional material. In other embodiments, substrate 23 and nanowires 24 can be different compositional materials. Preferably, substrate 23 and nanowires 24 are composed of the same compositional material.

The two or more nanowires 24 have first end 25 and a second end 26. The first end 25 of each of the two or more nanowires 26 is attached to the substrate 23. The distance between the first end and second end of each of the two or more nanowires is at least 5 nanometers, but is less than or equal to 50 microns. Moreover, the distance 27 (that is, the “pitch”) between the first end of a first nanowire and the first end of a second nanowire is greater than or equal to 50 nanometers and less than or equal to 5 microns. Lastly, the diameter 28 of each of the nanowires disclosed herein is at least 5 nanometers, but less than or equal to 1 micrometer. Still referring to FIG. 6A, each nanowire 24 has a longitudinal axis 29 between the first end 25 and the second end 26, and includes an angle 30 between the longitudinal axis 29 and the substrate 23. In a preferred embodiment disclosed herein, angle 30 is greater than or equal to 70 degrees and less than or equal to 90 degrees. In a more preferred embodiment, angle 30 is greater than or equal to 80 degrees and less than or equal to 90 degrees.

To enhance cell efficiency, the two or more nanowires 24 disclosed in this third embodiment possesses geometry. This geometry can be created by varying the placement of an electron beam during an electron beam writing step used to manufacture an anode disclosed herein, although other methods to manufacture such anodes may be utilized. While the following list is not meant to be all-inclusive, and only representative of embodiments that may be utilized, the geometry between nanowires 24 may be triangular, square, pentagonal, hexagonal, heptagonal and octagonal.

Referring to FIG. 6B, in a fourth embodiment, an organic photovoltaic solar cell is disclosed. The organic photovoltaic cell includes an anode and a cathode, the cathode being in electrical communication with the anode. The anode includes a substrate 23 and two or more nanowires 24. The substrate includes a conductive material, and in an exemplary embodiment, the conductive material is a transparent conducting oxide. While not meant to be limiting, the transparent conducting oxides from which the substrate 23 may be comprised include indium tin oxide, fluorine tin oxide, and doped zinc oxide. In an alternative embodiment, the conductive material may be metal.

In this fourth embodiment, the two or more nanowires 24 (illustrated as white vertical cylinders in FIG. 6B) include a conducting material, and in a preferred embodiment, the conducting material is a transparent conducting oxide. While not all inclusive of the transparent conducting oxides that may be utilized for the two or more nanowires 24 disclosed herein, in one embodiment, the transparent conducting oxides are chosen from the group comprising indium tin oxide, fluorine tin oxide, and doped zinc oxide. A conductive material layer (see, for example, ITO in FIG. 6B) is deposited onto a substrate (see, for example, YSZ substrate in FIG. 6B). Referring still to FIG. 6B, an insulating layer is deposited onto the conductive layer and subjected to an etching process to provide holes for growth of the two or more nanowires 24 to pass through. The insulating layer is composed typically of oxides, such as Al₂O₃ or SiO₂. The two or more nanowires 24 are grown from and are in electrical communication with the conductive material (ITO in FIG. 6B). In an alternative embodiment, the conducting material may be metal. In this alternative embodiment the metal may be chosen from the group comprising gold, silver, and copper.

The two or more nanowires 24 have a first end 25 and a second end 26. The first end 25 of each of the two or more nanowires 26 is attached to the substrate 23. The distance between the first end and second end of each of the two or more nanowires is at least 5 nanometers, but less than or equal to 50 microns. Moreover, the distance 27 (that is, the “pitch”) between the first end of a first nanowire and the first end of a second nanowire is at least 50 nanometers, but is less than or equal to 5 microns. Lastly, the diameter 28 of each of the nanowires disclosed herein is at least 5 nanometers and less than or equal to 1 micrometer. Referring to FIG. 6A, each nanowire 24 has a longitudinal axis 29 between the first end 25 and the second end 26, and includes an angle 30 between the longitudinal axis 29 and the substrate 23. In a preferred embodiment disclosed herein, angle 30 is greater than or equal to 70 degrees and less than or equal to 90 degrees. In a more preferred embodiment angle 30 is greater than or equal to 80 degrees and less than or equal to 90 degrees.

Furthermore, and referring to FIG. 6C, in an exemplary embodiment of a so called “inverted” organic photovoltaic cell disclosed herein, the anode nanowires 24 (A in FIGS. 6B, C) can be coated with a first layer B that includes zinc oxide (B in FIGS. 6B, C). Additionally, the nanowires can be further coated with a second layer C. Layer C can be an acceptor/donor mixed layer comprising P3HT/PCBM (C in FIGS. 6B, C). Alternatively, other embodiments can include a material comprising polymer material or small organic molecules, such as oligothiophene based donor-acceptor molecules, triphenylamine based amorphous donor-acceptor small molecules, dithienogermole-thienopynolodione-based polymer, PTPD3T, PBTI3T, and among others. These organic polymer materials can be blended with fullerene acceptor molecules to optimize performance. Another layer, D, can be MoOₓ (a hole conductor; D in FIGS. 6B, C), and the final outer layer E, can be either Ag or carbon for conducting the charges to the external circuit (E in FIGS. 6B, C).

To enhance cell efficiency, the two or more nanowires 24 of this embodiment possesses geometry. This geometry can be created by varying the placement of an electron beam during an electron beam writing step used to manufacture an anode disclosed herein, although other methods to manufacture such anodes may be utilized. While the following list is not meant to be all inclusive, and only representative of embodiments that may be utilized the geometry between nanowires 24 may be triangular, square, pentagonal, hexagonal, heptagonal and octagonal.

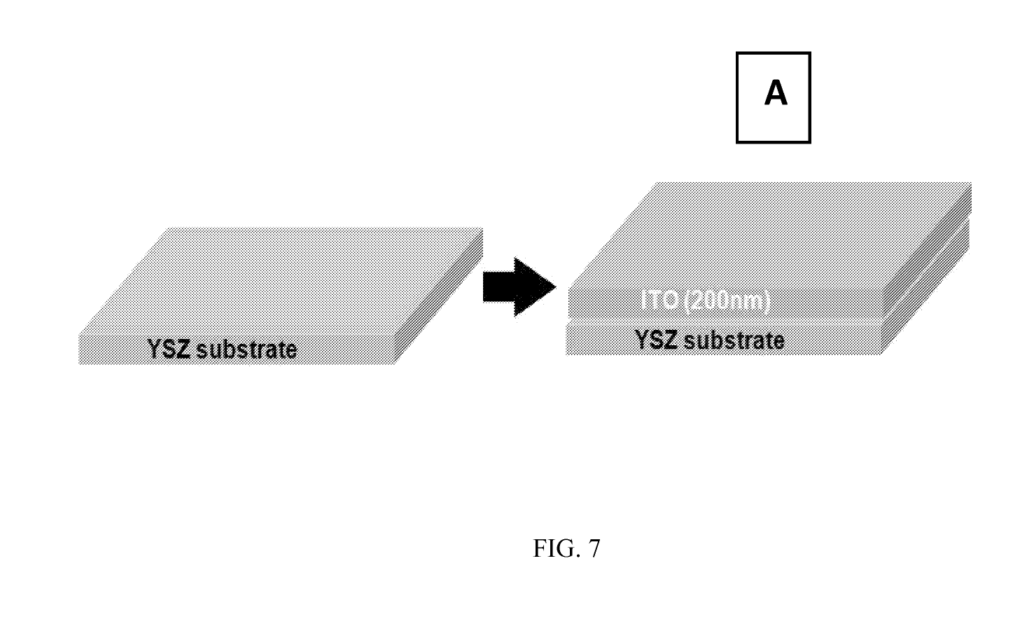

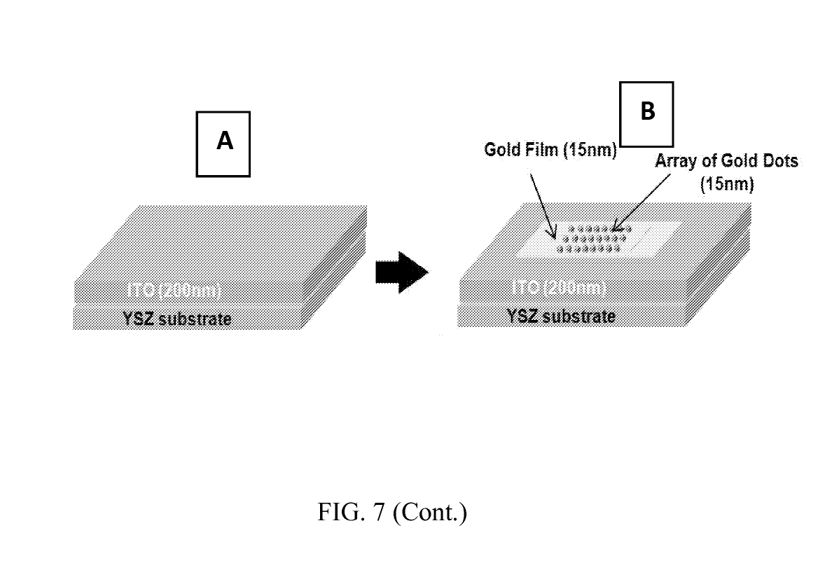

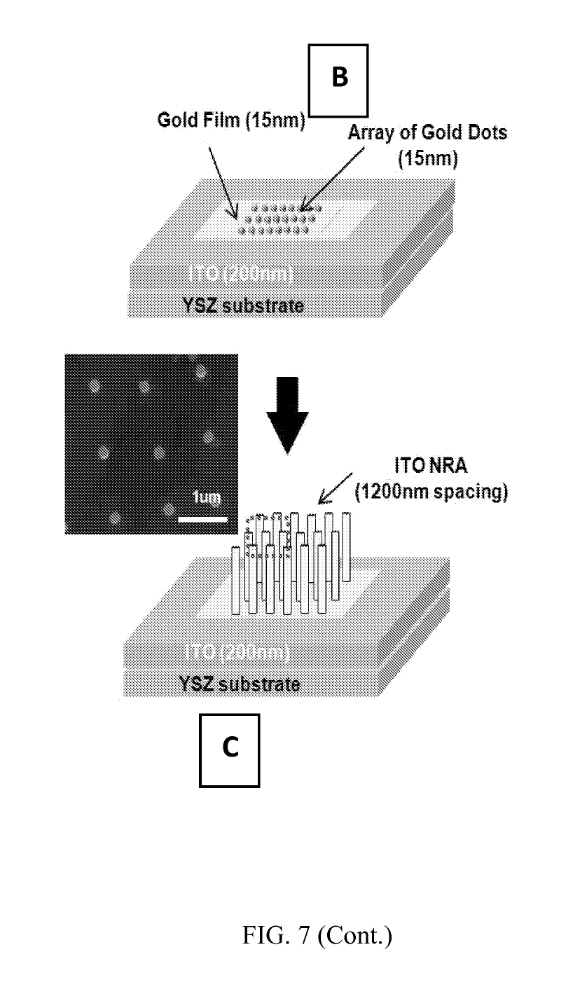

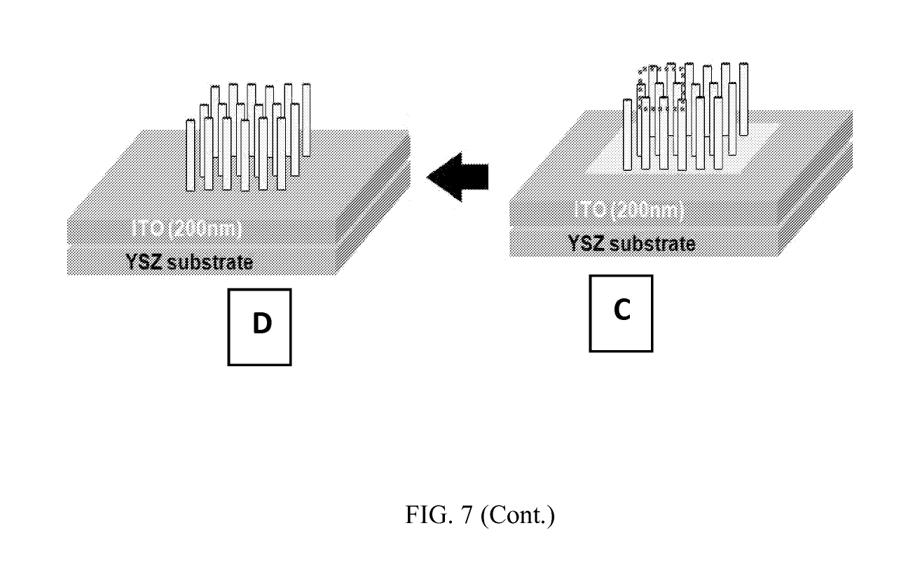

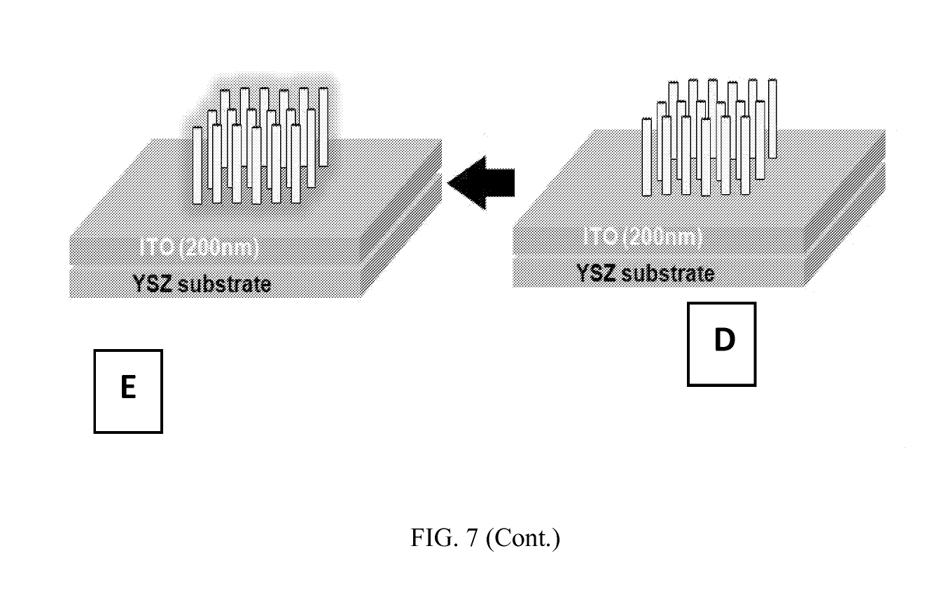

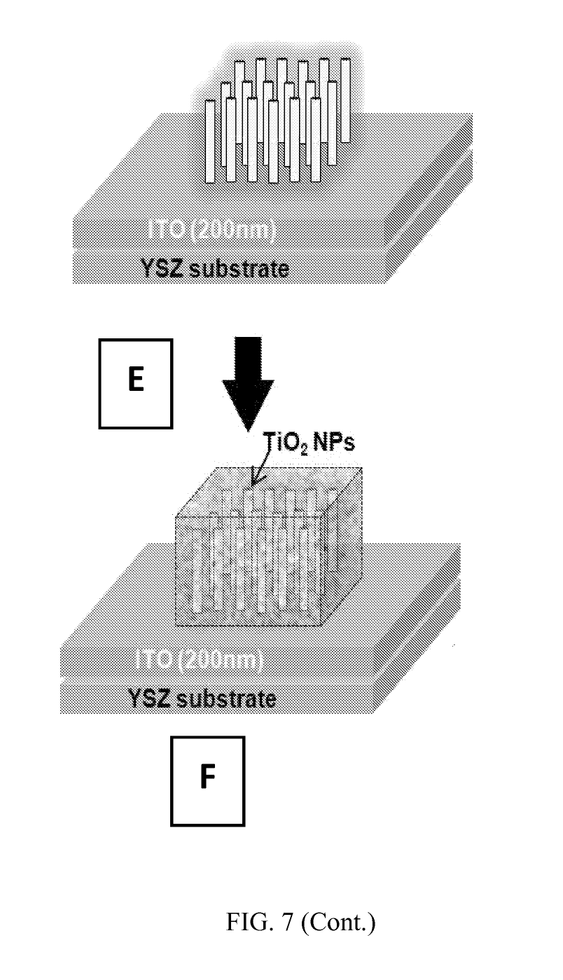

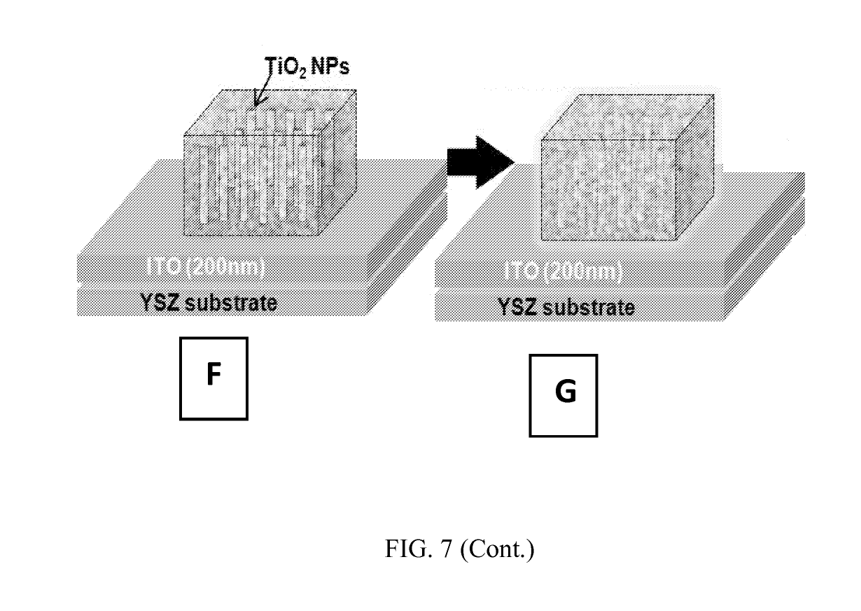

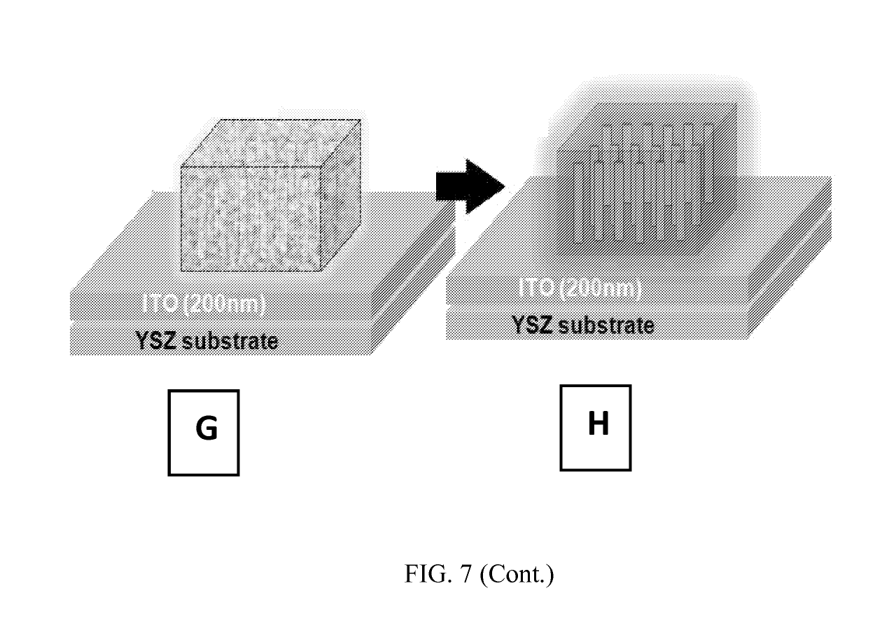

Referring to FIG. 7, in a fifth embodiment, a novel approach to making an anode for a solar cell that utilizes a nanoparticle based active layer is disclosed. This robust method allows the creation of anodes that demonstrate enhanced efficiency over traditional anodes for solar cells. The method includes the steps of providing a substrate structure A having a ITO layer deposited thereon by PLD deposition; providing a patterned array substrate structure B having an array of metal dots, a dopant material, and a metal oxide powder; heating the patterned array substrate structure B under conditions to grow nanowires from the patterned array substrate to create an anode with a nanowire array structure C; performing gold etching on structure C to remove the extraneous gold film from the structure C to form structure D; providing a precursor and water and exposing the structure D to the precursor and water under conditions to coat the nanowires by atomic layer deposition to yield an anode having a patterned, coated nanowire any of structure E. The resultant structure E can be infiltrated with TiO₂ nanoparticles by spraying deposition techniques to form structure F. The resultant structure F can be further processed with a TiO₂ post-treatment to yield structure G. The resultant structure G can be further processed by photosensitizing with an appropriate dye (for example, Ru-based complex dyes) to provide the completed anode structure H.

Any source of heating may be used for heating the patterned array substrate to achieve growth of the nanowires from the patterned array substrate to create the anode. A furnace is a preferred source for heating the patterned any substrate for this purpose.

In this fifth embodiment, the metal dots include gold. However, this example is not meant to be limiting. The dopant material may be chosen from the group comprising indium and fluorine. The metal oxide may be chosen from the group tin oxide and zinc oxide. Lastly, the precursor may be titanium tetrachloride.

Still referring to FIG. 7, a schematic of an exemplary embodiment of a solar cell structure I is illustrated that shows the anode component comprising the YSZ substrate, ITO layer, ITO outgrowth nanowires, a TiO₂ thin layer coating, infiltrated TiO₂ nanoparticles and the dye coating; an electrolyte; and a cathode comprising platinum-containing composition coated on a fluorine tin oxide (FTO) glass substrate.

### EXAMPLES

### Example 1

### Nanoparticle Based Active Layer Anode Fabrication

As a first step, 200 nm thick indium tin oxide (110) film was grown on yttria-stabilized zirconia (YSZ) (100) substrate by a pulsed laser deposition method (FIG. 7, structure A). Following that, a 3% 960K PMMA in Anisole (960 A3, MicroChem, Inc.) was spin-coated on the substrate (4000 rpm, 60 s). Electron-beam writing was then performed on FEI Quanta 600F environment SEM to write hole (100 nm in diameter) arrays with different pitch distance (from 600 to 1600 nm). The exposed sample was subsequently developed and titanium (1 nm) and gold films (10 nm) were deposited by electron beam evaporation (with Edward Auto 600; gold shot used is 99.99% trace metal basis from Aldrich.; titanium shot is 99.996% trace metal basis from Ted Pella), followed by lift-off in acetone. Reactive Ion Etching (RIE) to remove residual ITO film was done at room temperature using Samco RIE-10NR reactive ion etcher with CH₄ and H₂ (1:4) gases at a pressure of 60 mTorr and a power of 100 W (FIG. 7, structure B). This process was followed by oxygen plasma clean at 260 W, to remove the remaining polymer residues (FIG. 7, structure B). Using a single-zone quartz-tube furnace, ITO nanowires were grown on patterned substrates (FIG. 7, structures C and D). A uniform TiO₂ thin layer of thickness of ˜10 nm was deposited on ITO nanowires using an atomic layer deposition system (ALD) with a deposition rate 0.6 nm per cycle (FIG. 7, structure E). Vapors of deionized water and titanium tetrachloride (TiCl₄, 99.9%, Aldrich) were used as precursors under 0.6 s exposure time and 20 s pumping time and substrates were kept at 100° C. A post-annealing treatment at 600° C. for 2 hr in ambient condition was made. The ALD deposited TiO₂ layer assured no electrical shorts between the anode electrode and the liquid electrolyte of a dye-sensitized solar cell.

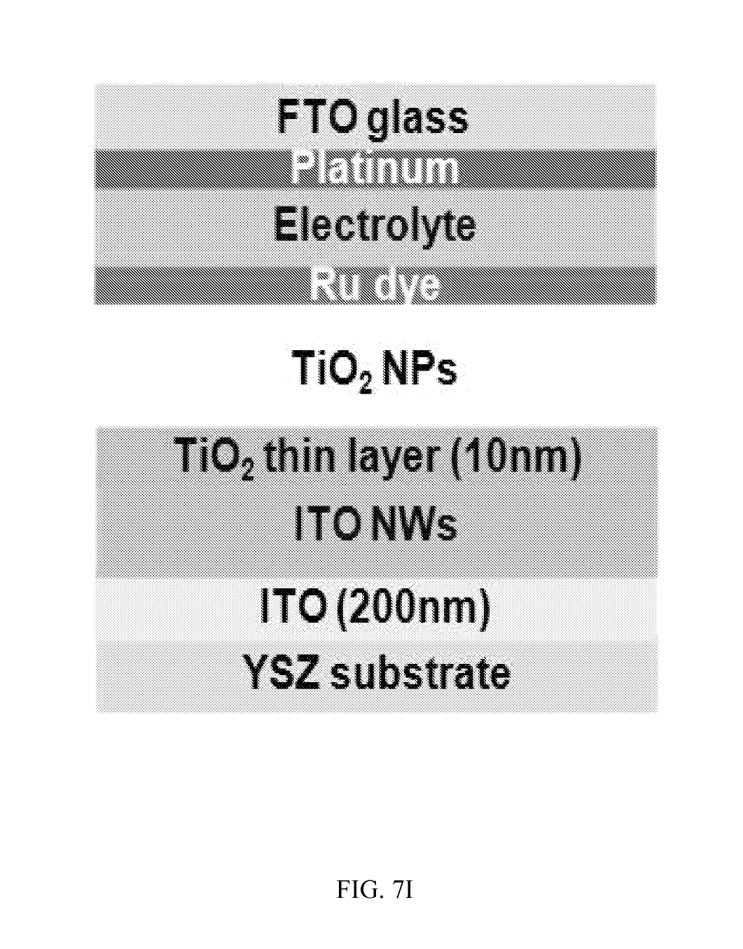

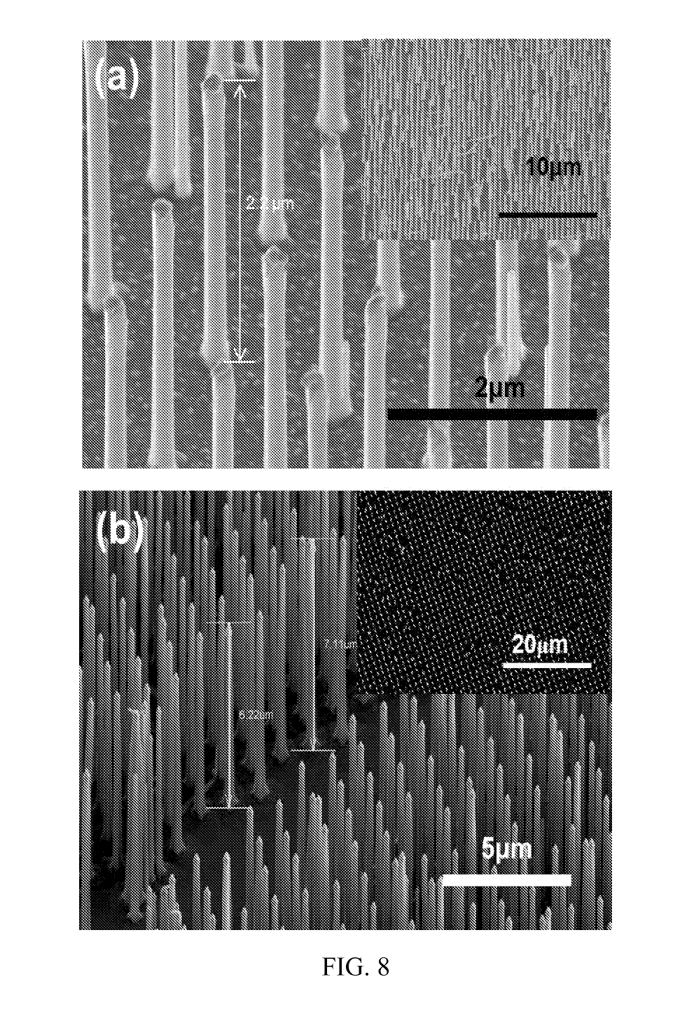

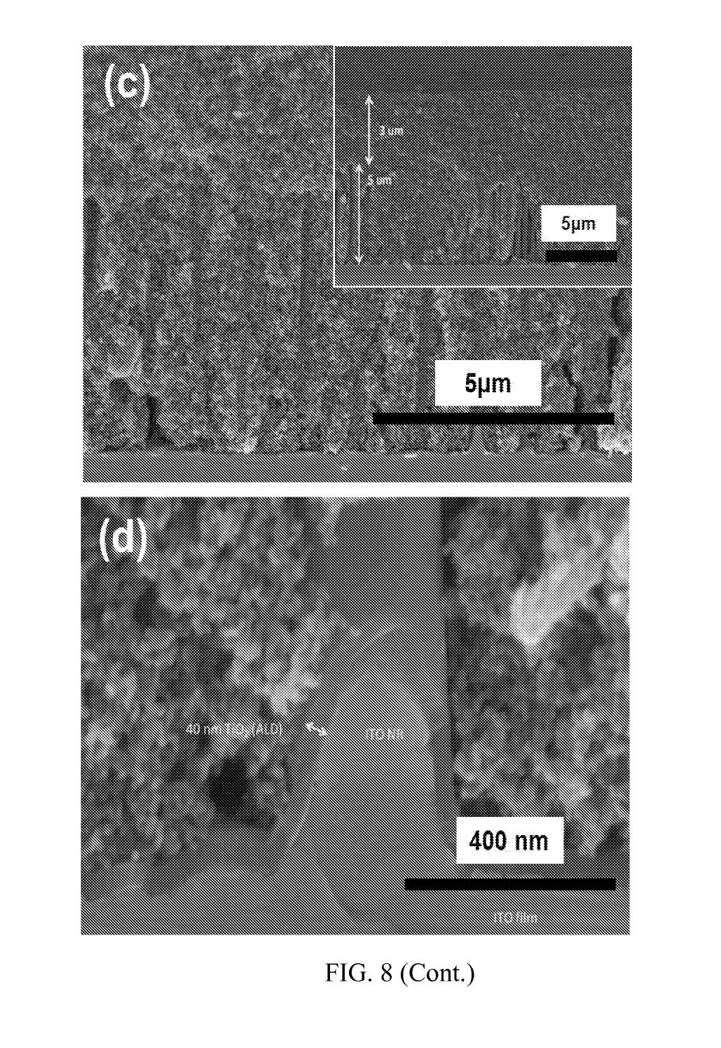

FIGS. 8A and 8B illustrate some anodes created with the foregoing procedure. Together they demonstrate that the nanowire length may be varied by adjusting the nanowire growth process in FIGS. 8C and 8D. These example lengths are not meant to be limiting, as the overall length of the nanowires in this anode may be greater or less than the lengths illustrated in FIG. 7.

### Example 2

### Dye-Sensitized Solar Cell Cathode Fabrication

The cathode was fabricated by coating fluorine tin oxide glass (FTO) substrate with a thin layer of a 6 mM solution of H₂PtCl₆ in isopropanol and it was heated at 400° C. for 20 min.

### Example 3

### Dye-Sensitized Solar Cell Fabrication

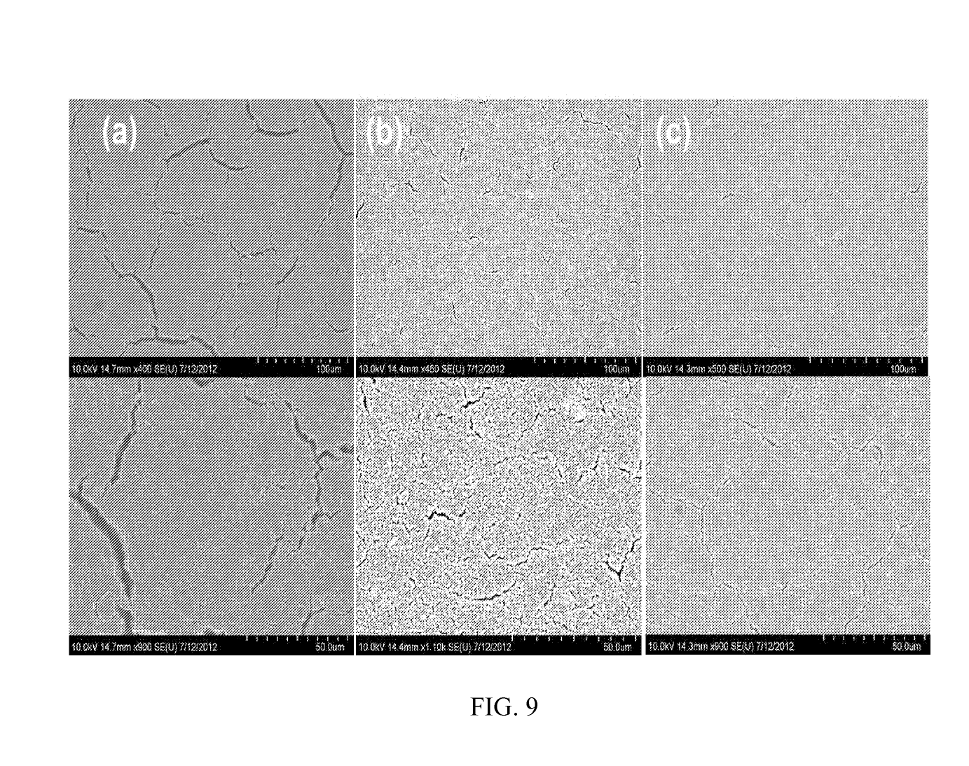

An anode as in Example 1 was provided. Subsequently, hydrothermally prepared titanium dioxide nanoparticles (NP) were electro-sprayed into the voids among the ITO nanowires. For the process, a TiO₂ nanoparticle solution was prepared by mixing 10 wt % hydrothermal TiO₂ nanoparticles in 0.1M acetic acid, 0.06 g polyethylene glycol (PEG, Fluka, Mw=20 000) and 100 μL of Triton X-100 together. This solution was electro-sprayed using air brush (Speedaire, model 4RR09B) under 40 psi air pressure with nitrogen gas. The spray head was situated at a distance of ˜10 cm from the ITO nanowire substrates. TiO₂-coated ITO nanowire electrode was gradually calcined under an air flow at 160° C. for 16 min, at 320° C. for 10 min, at 600° C. for 30 min. Through the heating process, the organic additives were removed as well as sintered the TiO₂ nanoparticles to obtain an electrically connected network. However, the organic additives were responsible for cracking TiO₂ surface during annealing (FIG. 9A).

In order to cover a part of cracking surface, post-treatment process was utilized (FIG. 7, structure G). As a first step, a solution of 0.2M titanium bis(ethyl acetoacetate)diisopropoxide (C₁₈H₃₄O₈Ti, Aldrich, 99.9%) in 1-butanol (Aldrich, 99.8%) was electro-sprayed on TiO₂ NPs film using air brush. Ti coated TiO₂ nanoparticle film was heated to 500° C. from room temperature in 30 min (FIG. 7, structure G and FIG. 9B). Next, a TiCl₄ aqueous solution was applied to Ti coated TiO₂ nanoparticle film. An aqueous stock solution of 2 M TiCl₄ was diluted to 0.02 M in deionized water. Sintered electrodes were immersed into this solution and stored in an oven at 70° C. for 20 min in a closed vessel. After flushing with deionized water and drying, the electrodes were gradually sintered again at 150° C. for 15 min, at 320° C. for 10 min, at 500° C. for 30 min (FIG. 7 structure G and FIG. 9C).

For photosensitization, the ITO nanowire/TiO₂ nanoparticle electrode was immersed in the ethanol solution containing purified 3×10 M cis-di(thiocynato)-N,N′-bis(2,2′-bipyridyl-4-caboxylic acid-4′-tetrabutylammonium carboxylate) ruthenium (II) (N719, Solaronix) for 18 h at room temperature (FIG. 7, structure H). The liquid electrolyte was prepared by dissolving 0.6 M of 1-butyl-3-methylimidazolium iodide (BMII), 0.03 M of iodine, 0.1M of guanidiniumthiocyanate and 0.6 M of 4-tert-butylpyridine in acetonitrile and valeronitrile (86:16 v/v) (FIG. 7, included in structure I). These steps created the anode half of the device.

FIG. 7 structures E and F illustrate the infiltration of nanoparticles in an anode half disclosed herein. Further, FIG. 7 structure E included a non-conducting material having a thickness of about 40 nanometers. However, this particular example of non-conducting material thickness is not meant to be limiting, as the thickness of the non-conducting material may be greater than or less than in this particular illustration.

Subsequently, the anode half was sealed together with the cathode of Example 2 with thermal melt polymer film (24 μm thick, DuPont) to create a completed solar cell (FIG. 7, structure I).

### Example 4

### Quantum Dot Sensitized Solar Cell Cathode Fabrication (Prophetic)

A cathode will be fabricated by coating fluorine tin oxide glass (FTO) substrate with a thin layer of a 6 mM solution of H₂PtCl₆ in isopropanol and it will be heated at 400° C. for 20 min.

### Example 5

### Quantum Dot Sensitized Solar Cell Fabrication (Prophetic)

An anode as in Example 1 will be provided. Subsequently, hydrothermally prepared titanium dioxide nanoparticles (NP) will be electro-sprayed into the voids among the ITO nanowires. For the process, a TiO₂ nanoparticle solution will be prepared by mixing 10 wt % hydrothermal TiO₂ NPs in 0.1M acetic acid, 0.06 g polyethylene glycol (PEG, Fluka, Mw=20 000) and 100 μL of Triton X-100 together. This solution will be electro-sprayed using air brush (Speedaire, model 4RR09B) under 40 psi air pressure with nitrogen gas. The spray head will be situated at a distance of ˜10 cm from the ITO nanowire substrates. TiO₂ coated ITO nanowire electrode will be gradually calcined under an air flow at 160° C. for 16 min, at 320° C. for 10 min, at 600° C. for 30 min. As a post-treatment, a solution of 0.2M titanium bis(ethyl acetoacetate)diisopropoxide (C₁₈H₃₄O₈Ti, Aldrich, 99.9%) in 1-butanol (Aldrich, 99.8%) will be coated on ITO NWs/TiO₂ nanoparticle film and sintered at 460° C. for 30 min. For photosensitization, various quantum dots (CdSe, CdS, InP, InAs, and PbS, etc.) may be used as sensitizers of the TiO₂ nanoparticle/ITO nanowire film. A chemical bath deposition (CBD) technique will be employed to assemble CdS and CdSe quantum dots in the sequence on the photoanodes. All the QDs (CdS and CdSe) depositions will be carried out at 10° C. CdS will be deposited with an aqueous solution with the composition of 20 mM CdCl₂, 66 mM NH₄Cl, 140 mM thiourea and 230 mM ammonia with a final pH ca. 9.6 for about 30 min. The films will then be washed with water completely. Subsequently, the CdSe quantum dots will be deposited by mixing an aqueous solution with 26 mM CdSO₄, 40 mM N(CH₂COONa)₃ and 26 mM Na₂SeSO₃. The CdSe deposition process will be maintained for 6.6 h. Finally, the photoanodes will be passivated with ZnS by twice dipping into 0.1 M Zn(CH₃COO)₂ and Na₂S aqueous solution for 1 min alternately. Subsequently, liquid electrolyte will be prepared by dissolving 0.6 M of 1-butyl-3-methylimidazolium iodide (BMII), 0.03 M of iodine, 0.1M of guanidiniumthiocyanate and 0.6 M of 4-tert-butylpyridine in acetonitrile and valeronitrile (86:16 v/v). These steps will create the anode half of the device.

Subsequently, the anode half will be sealed together with the cathode of Example 4 with thermal melt polymer film (24 μm thick, DuPont) to create a completed solar cell.

### Example 6

### Organic Photovoltaic Solar Cell Fabrication (Prophetic)

As a first step, 200 nm thick indium tin oxide (ITO) film will be grown on yttria-stabilized zirconia (YSZ) (100) substrate by a pulsed laser deposition method. Following that, a 3% 960K PMMA in Anisole (960 A3, MicroChem, Inc.) will be spin-coated on the substrate (4000 rpm, 60 s). Electron-beam writing will then be performed on FEI Quanta 600F environment SEM to write hole (100 nm in diameter) arrays with different pitch distance (from 600 to 1600 nm). The exposed sample will subsequently be developed and titanium (1 nm) and gold films (10 nm) will be deposited by electron beam evaporation (with Edward Auto 600; gold shot used is 99.99% trace metal basis from Aldrich.; titanium shot is 99.996% trace metal basis from Ted Pella), followed by lift-off in acetone. Reactive Ion Etching (RIE) to remove residual ITO film will be done at room temperature using Samco RIE-10NR reactive ion etcher with CH₄ and H₂ (1:4) gases at a pressure of 60 mTorr and a power of 100 W. This process will be followed by oxygen plasma clean at 260 W, to remove the remaining polymer residues. Then, using a single-zone quartz-tube furnace, ITO nanowires will be grown on patterned substrates.

Next, 0.6 mg of P3HT and 0.6 mg of PCBM may be dissolved in 10 mL of the 1,1,2,2-tetrachloroethane (TCE)/chlorobenzene (CB) mixtures. PEDOT doped with PSS (PEDOT/PSS) may be diluted using the same volume of CH₃OH. The PEDOT/PSS solution will be sprayed on ITO nanowires and dried at 110° C. for 10 min. The thickness of the PEDOT/PSS buffer layer may be between 10-40 nm. For the spraying, 12 mg of P3HT and 10 mg of PCBM will be dissolved in 2-10 mL of TCE/CB (6:6) and then stirred for more than 3 h prior to use. The thickness of the active layers of the organic photovoltaic solar cell should be ˜100 nm. Subsequently, the films will then be annealed on a hot plate in a glove box at 120° C. for 10 min.

Subsequently, the active-layer deposited anodes will then be transferred to a vacuum evaporation chamber in order to deposit the LiF/Al back-side cathode. The LiF/Al cathodes (0.6 nm/130 nm ˜1 μm) will be deposited using a shadow mask at 10⁻⁶ Torr. The rates used will be about 0.1 Å/sec for LiF (Acros; 99.98%) and ≈2 Å/sec for Al with a chamber pressure of 1.1×10⁻⁶ torr. The cathodes will then be deposited through a shadow mask with two 2.0-mm strips perpendicular to the two patterned ITO strips to make four devices per substrate. Finally, the organic photovoltaic solar cells will be encapsulated with a glass slide by using UV-curable epoxy (Electro-Lite ELC-2600), which will be cured in a UV chamber inside of the glove box

For electro-spray deposition, the P3HT/PCBM solution will be loaded into a 10-mL glass syringe equipped with a 30-G-sized hypodermic needle. The distance between the solution-loaded tip and the substrate will be maintained between about 10-16 cm, and the applied voltage will be between about 16-18 kV. Next, the P3HT/PCBM solution will be injected through the nozzle at a rate of 30-40 μL min⁻¹. During the deposition, the solution-loaded syringe will be shuttled with a robotic arm, and the substrate-loaded stage will be moved in the x-y direction.

### Example 7

### Dye-Sensitized Solar Cell Measurements Fabricated with Post-Treatment Nanoparticles

The effect of a post-treated TiO₂ nanoparticle sample was investigated (FIG. 8). As illustrated in Table 1, the 2-step post treated TiO₂ NPs film device showed a VOC, JSC, fill factor (FF), and power conversion efficiency (PCE) of 814 mV, 15.2 mA cm⁻², 72.2%, and 8.93%, respectively, at a photoelectrode thickness of ca. 7.2 μm; the pristine-TiO₂ film devices gave 802 mV, 11.2 mA cm⁻², 77.4%, and 6.96% at the same thickness.

TABLE 1
JV Characteristics of TiO₂ Nanoparticle Films

| | | JV characteristics | | | | |
|---|---|---|---|---|---|---|
| | Area | V_{OC} | J_{SC} | FF | EFF | Increasing rate |
| | (cm²) | (V) | (mA/cm²) | (%) | (%) | (%) |
| (a) | 0.184 | 0.802 | 11.2 | 77.4 | 6.96 | |
| (b) | 0.191 | 0.811 | 12.9 | 77.0 | 8.06 | 15.8 |
| (c) | 0.201 | 0.814 | 15.2 | 72.2 | 8.93 | 22.1 |

(a) Pristine TiO₂ nanoparticle film;
(b) (Ti-Ti)₂ nanoparticle film treated with a Ti Sol; and
(c) Ti-TO₂ nanoparticle film treated with TiCl₄

### Example 8

### Dye-Sensitized Solar Cell Electrical Measurements

Dye-sensitized solar cell (DSSC) devices were evaluated under 100 mW/cm² AM1.6G simulated sunlight with a class A solar cell analyzer (Spectra Nova Tech). A silicon solar cell fitted with a KG3 filter tested and certified by the National Renewable Energy Laboratory (NREL) was used for calibration. The KG3 filter accounts for the different light absorption between the dye sensitized solar cell and the silicon solar cell, and it ensures that the spectral mismatch correction factor approaches unity. The electrochemical impedance results were measured under the same light illumination with an impedance analyzer (Solartron 1260), and a potentiostat (Solartron 1287) when the device was applied at its V. An additional low amplitude modulation sinusoidal voltage of 10 mVᵣₘₛ was also applied between an anode and cathode of a device over the frequency range of 0.06-160 k Hz. The J-V characteristics of the cells were measured using the masked frame method that has been adopted to limit photocurrent over estimation arising from light-guiding effects that occur as light passes through the conductive glass electrode.

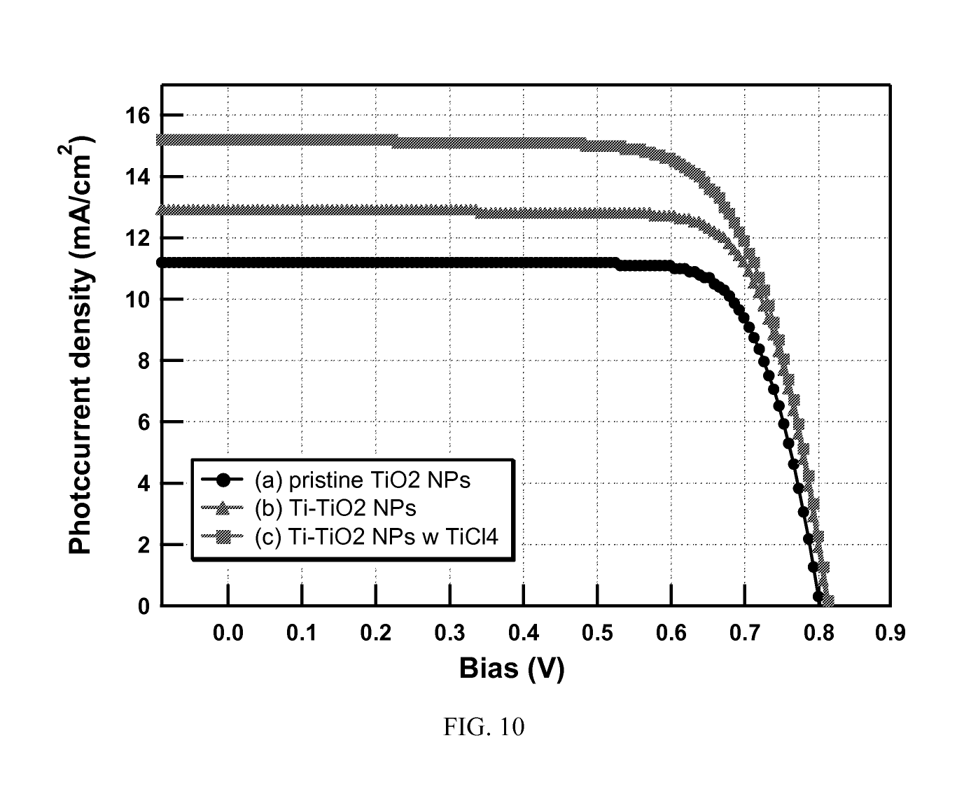

Data comparing a traditional solar cell and a solar cell utilizing an anode disclosed herein show an improvement in efficiency in the range of 16 to 40% and has the cell performance data based on an anode disclosed herein. It should be noted that the highest cell efficiency is 11% (with 7 micron nanowires) (FIG. 10 and Table 2). It is anticipated that one can reach 16% by lengthening the nanowires to between 10-15 microns. These results have demonstrated the highest efficiency to date with N719 dye.

FIG. 10 shows J-V curves of the traditional and solar cells utilizing an anode disclosed herein for different TiO₂ nanoparticle thicknesses. Table 2 shows the corresponding EIS and current voltage characteristics.

TABLE 2
EIS and Current Voltage Characteristics of Solar Cells lacking and containing the anode disclosed herein.

| | | | | JV characteristics | | | | | | | | |
|---|---|---|---|---|---|---|---|---|---|---|---|---|
| | Total | | w/o 3D PhC | | | | | | w 3D PhC | | | |
| DSSC | Thickness | Area | V_{OC} | J_{SC} | FF | EFF | R₂ | R_{IR} | V_{OC} | J_{SC} | FF | EFF |
| type | (μm) | (cm²) | (V) | (mA/cm²) | (%) | (%) | (Ωcm²) | (Ωcm2) | (V) | (mA/cm²) | (%) | (%) |
| 2D | ≈3 | 0.236 | 0.928 | 2.70 | 72.6 | 1.82 | 6.93 | 9.61 | 0.929 | 3.19 | 72.4 | 2.14 |
| | ≈7 | 0.286 | 0.869 | 10.6 | 72.0 | 6.66 | 6.68 | 8.24 | 0.866 | 12.6 | 72.4 | 7.90 |
| | ≈9 | 0.249 | 0.796 | 13.8 | 71.4 | 7.82 | 3.91 | 6.36 | 0.796 | 16.7 | 69.2 | 8.66 |
| 3D | ≈3 | 0.201 | 0.883 | 7.12 | 74.0 | 4.66 | 6.09 | 7.70 | 0.882 | 8.62 | 73.6 | 6.60 |
| | ≈7 | 0.212 | 0.866 | 14.0 | 74.0 | 8.86 | 2.66 | 4.68 | 0.860 | 16.9 | 73.2 | 10.7 |
| | ≈9 | 0.201 | 0.808 | 16.2 | 74.9 | 9.20 | 2.28 | 4.66 | 0.809 | 17.8 | 74.8 | 10.9 |

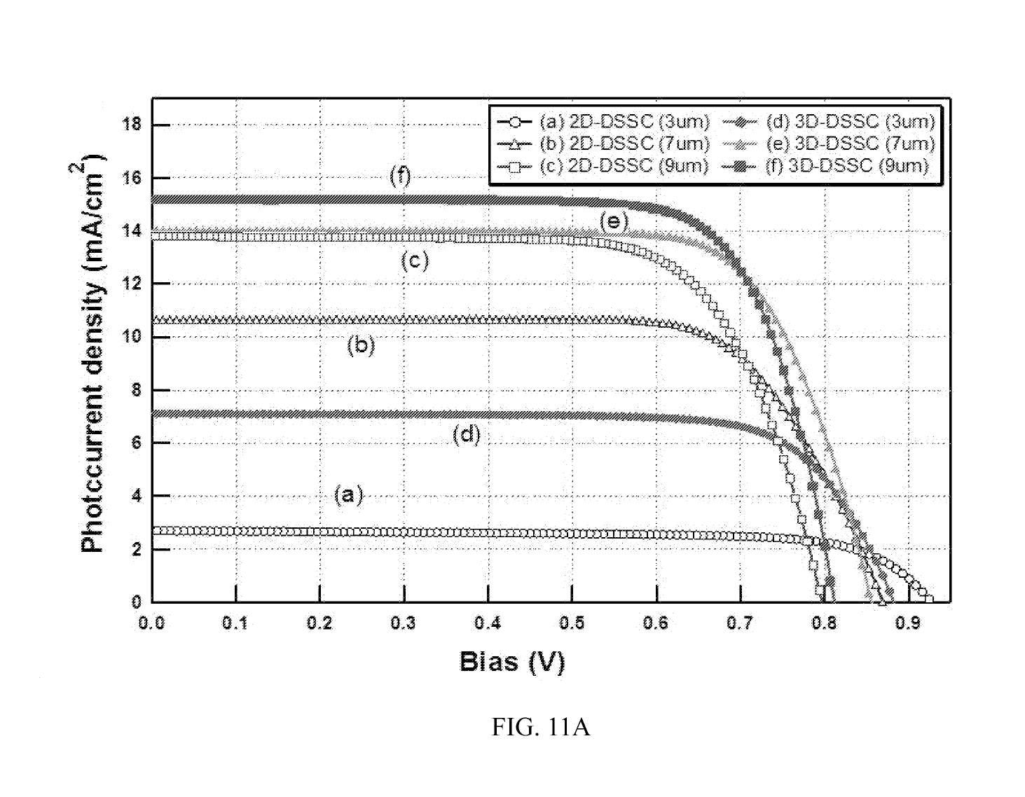

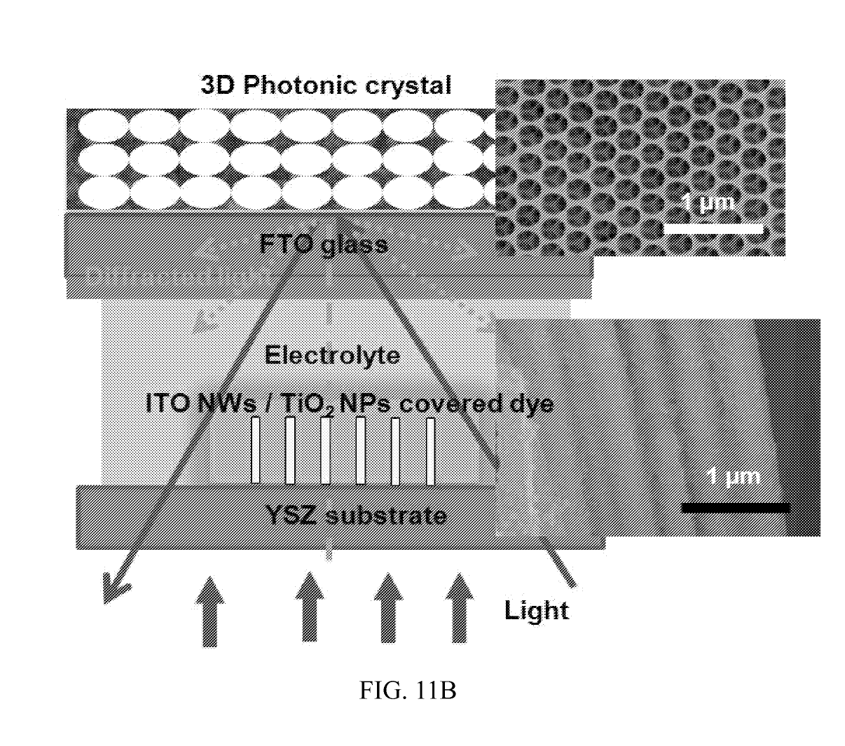

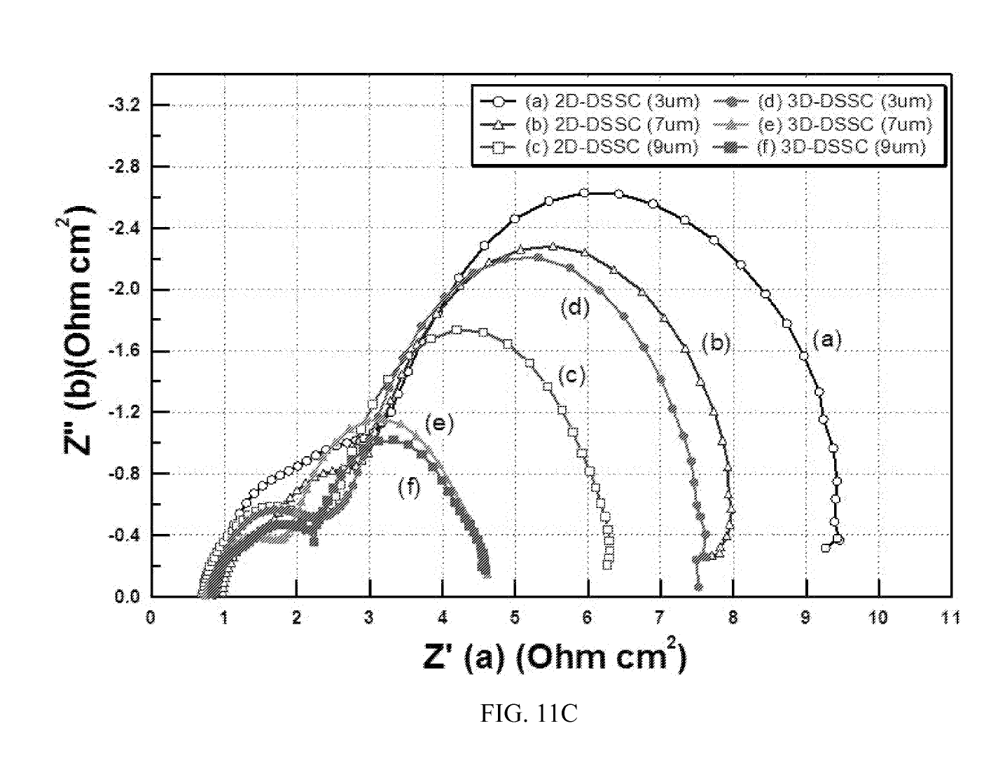

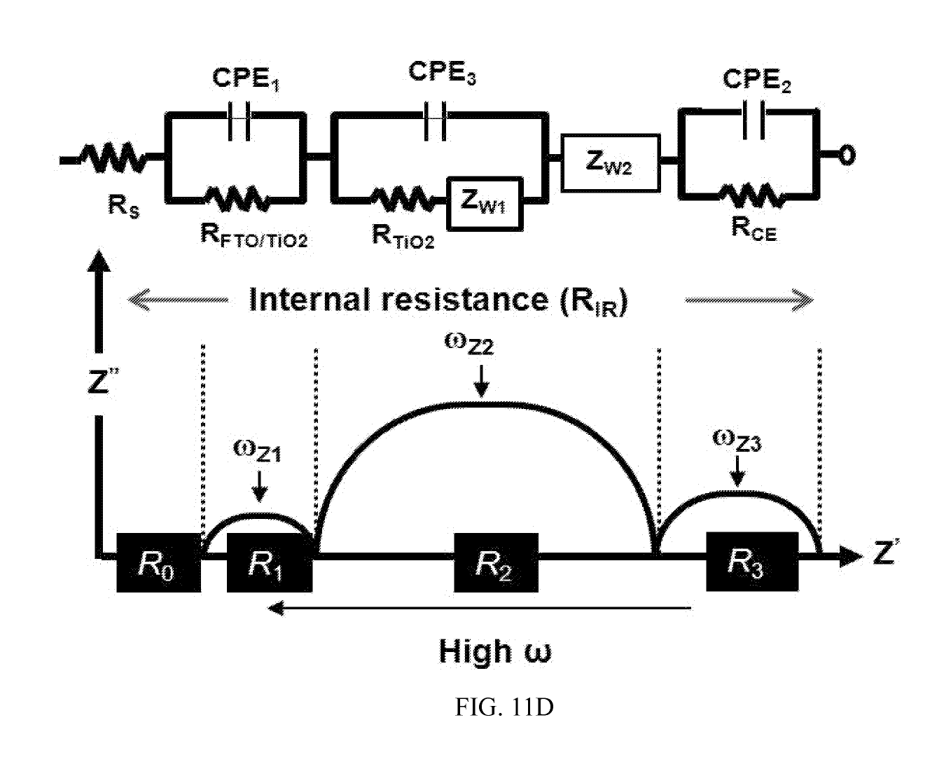

Their performances are summarized in FIG. 11. Referring to FIG. 11A, a considerably enhanced short-circuit current density (J_{sc}) was achieved with the solar cell disclosed herein. The J_{sc} is seen to increase with the film thickness, as expected. In the case of solar cell disclosed herein with ˜3 μm, the J_{sc} and energy efficiency (ii) was about 164% and 166% higher compared to that of the traditional solar cell of the same nanoparticle film thickness. However, as the total thickness increases (that is, as the ITO nanowires become longer), the rate of increasing energy efficiency for the solar cell disclosed herein decreases to about 33.2% and 17.6% in comparison with traditional solar cell for 7 μm and 9 μm thick film, respectively. This result may be able to be explained by noting that for longer ITO nanowires, it is much more difficult to completely fill the gaps between ITO nanowires with the described spray method.

The enhanced photocurrent of a solar cell utilizing an anode disclosed herein may be attributed to the lower series resistance of the cell and it facilitates photocarrier transport. In addition, it is seen that the 3 μm sample for a solar cell utilizing an anode disclosed herein has a JSC that is 2.6 times higher than the traditional solar cell of the same thickness (FIG. 11A). This superior unexpected property is due to the improved cell configuration.

The effect on the internal charge transport can be simply obtained by EIS measurements. The detailed internal series resistance (R_{IR}) data are summarized in FIG. 10 and FIG. 11. The internal series resistance elements are related to the sheet resistance of FTO (R₀), the charge transfer processes at the counter electrode (R₁), the charge transportation at the TiO₂/dye/electrolyte interface (R₂), diffusion in the electrolyte (R₃). The internal series resistance (R_{IR}) can then be described as R_{IR}=R₀+R₁+R₂+R₃ (FIG. 11D). The R_{IR} of the 3-D DSSC has an average of 30.8% lower value than that of the traditional solar cell (see, for example, FIG. 11C). The decreased value of R_{IR} for the solar cell utilizing an anode disclosed herein may be from the smaller resistivity value contribution of the R₂ which is due the interface between TiO₂/dye/electrolyte.

FIG. 11B illustrates the configuration of a solar cell utilizing an anode disclosed herein along with a 3-D photonic crystal (PhC). This arrangement was also used as a traditional solar cell. The overall cell efficiency can be increased by as much as 12% by efficiently reflecting and diffraction at opposite end of the cell, the cathode electrode side. Therefore, a solar cell utilizing an anode disclosed herein combined with 3-D PhC gives a J_{sc} of 17.8 mA/cm², a V_{oc} of 0.809 V, a fill factor of 74.8% and efficiency of 10.9%. The efficiency of a solar cell utilizing an anode disclosed herein was improved by as much as 26.9% compared with that of traditional solar cell with 3-D PhC photon confinement (see also Table 2).

### Example 9

### Nano-Rod Geometries Having a Non-Patterned, Random Configuration

The ITO nano-rods were grown without patterning (i.e., with a random configuration; see FIG. 12). In this case, a thin gold film was deposited onto a YSZ substrate prior to the furnace growth as described herein. By heating the gold film, it melts and turns into many nano-size particles which in turn serve as the seeds for the ITO nano-rod growth. In this case, the nano-rods range 3-5 microns in height and their separation on average is about 500 nm.

It should be understood that the methods, procedures, operations, devices, and systems illustrated in FIGS. 4 through 12 may be modified without departing from the spirit of the present disclosure. For example, these methods, procedures, operations, devices and systems may comprise more or fewer steps or components than appear herein, and these steps or components may be combined with one another, in part or in whole.

Furthermore, the present disclosure is not to be limited in terms of the particular embodiments described in this application, which are intended as illustrations of various embodiments. Many modifications and variations can be made without departing from its scope and spirit. Functionally equivalent methods and apparatuses within the scope of the disclosure, in addition to those enumerated herein, will be apparent to those skilled in the art from the foregoing descriptions.

### TERMINOLOGY AND DEFINITIONS

The terminology used herein is for the purpose of describing particular embodiments only, and is not intended to be limiting. With respect to the use of substantially, any plural and/or singular terms herein, those having skill in the art can translate from the plural as is appropriate to the context and/or application. The various singular/plural permutations may be expressly set forth herein for the sake of clarity.

Terms used herein are intended as “open” terms (e.g., the term “including” should be interpreted as “including but not limited to,” the term “having” should be interpreted as “having at least,” the term “includes” should be interpreted as “includes but is not limited to,” etc.).

Furthermore, in those instances where a convention analogous to “at least one of A, B and C, etc.” is used, in general such a construction is intended in the sense of one having ordinary skill in the art would understand the convention (e.g., “a system having at least one of A, B and C” would include but not be limited to systems that have A alone, B alone, C alone, A and B together, A and C together, B and C together, and/or A, B, and C together.). It will be further understood by those within the art that virtually any disjunctive word and/or phrase presenting two or more alternative terms, whether in the description or figures, should be understood to contemplate the possibilities of including one of the terms, either of the terms, or both terms. For example, the phrase “A or B” will be understood to include the possibilities of “A” or B or “A and B.”

All language such as “up to,” “at least,” “greater than,” “less than,” and the like, include the number recited and refer to ranges which can subsequently be broken down into subranges as discussed above.

A range includes each individual member. Thus, for example, a group having 1-3 members refers to groups having 1, 2, or 3 members. Similarly, a group having 6 members refers to groups having 1, 2, 3, 4, or 6 members, and so forth.

The modal verb “may” refers to the preferred use or selection of one or more options or choices among the several described embodiments or features contained within the same. Where no options or choices are disclosed regarding a particular embodiment or feature contained in the same, the modal verb “may” refers to an affirmative act regarding how to make or use and aspect of a described embodiment or feature contained in the same, or a definitive decision to use a specific skill regarding a described embodiment or feature contained in the same. In this latter context, the modal verb “may” has the same meaning and connotation as the auxiliary verb “can.”

What is claimed is:

1. An anode for use in a solar cell utilizing a nanoparticle based active layer, comprising:
a substrate comprised of a conductive material; and
two or more nanowires, the nanowires comprised of a conducting material, the nanowires having a first end and a second end with a longitudinal axis therebetween, the first end of each nanowire attached to said substrate, the nanowires coated with a non-conducting material.

2. The anode of claim 1 wherein the conductive material is a metal.

3. The anode of claim 1 wherein the conductive material is a transparent conducting oxide.

4. The anode of claim 1 wherein the conducting material is a metal.

5. The anode of claim 1 wherein the conducting material is a transparent conducting oxide.

6. The anode of claim 1 wherein the non-conducting material is a semiconducting material.

7. The anode of claim 1 wherein the two or more nanowires possess geometry with respect to each other.

8. A solar cell utilizing a nanoparticle based active layer, comprising:
an anode,
said anode comprised of a substrate having two or more nanowires attached thereto, the substrate made of a conductive material, the two or more nanowires comprised of a conducting material having a first end and a second end with a longitudinal axis therebetween with the first end attached to the substrate and the nanowires coated with a non-conducting material;
two or more nanoparticles disposed between said nanowires, the nanoparticles comprised of a non-conductive material; and
a cathode, said cathode in electrical communication with said anode.

9. The solar cell of claim 8 wherein the conductive material is a metal.

10. The solar cell of claim 8 wherein the conductive material is a transparent conducting oxide.

11. The solar cell of claim 8 wherein the conducting material is a metal.

12. The solar cell of claim 8 wherein the conducting material is a transparent conducting oxide.

13. The solar cell of claim 8 wherein the non-conducting material is a semiconducting material

14. The solar cell of claim 8 wherein the nanoparticle is sensitized with a dye.

15. The solar cell of claim 8 wherein the nanoparticle is sensitized with a quantum dot/rod.

16. A method for manufacturing an anode for use in a solar cell utilizing a nanoparticle based active layer, comprising:
providing an anode substrate;
heating the anode substrate under conditions such that nanowires grow from the anode substrate to create an anode having a geometry of nanowires;
providing a precursor and water; and
exposing the anode having a geometry of nanowires to the precursor and water under conditions to coat the nanowires.

17. The method of claim 16, wherein the geometry of nanowires comprises a non-patterned, random configuration of nanowires.

18. The method of claim 16, wherein the anode substrate comprises a plurality of metal dots, a dopant material, and a metal oxide powder.

19. The method of claim 18, wherein the plurality of metal dots are arranged in a patterned array.

20. The method of claim 18, wherein
the plurality of metal dots comprise gold,
the dopant material is chosen from the group indium and fluorine,
the metal oxide is chosen from the group tin oxide and zinc oxide, and
the precursor is titanium tetrachloride.
